(19) United States
(12) Patent Application Publication
(10) Pub. No.: US 2023/0327051 A1
(43) Pub. Date: Oct. 12, 2023

(54) DISPLAY DEVICE AND MANUFACTURING METHOD THEREOF

(71) Applicant: Samsung Display Co., LTD., Yongin-si (KR)

(72) Inventors: Do Yeong PARK, Yongin-si (KR); Chong Chul CHAI, Yongin-si (KR); Jin Seon KWAK, Yongin-si (KR); Kyung Bae KIM, Yongin-si (KR)

(21) Appl. No.: 18/131,827

(22) Filed: Apr. 6, 2023

(30) Foreign Application Priority Data
Apr. 7, 2022 (KR) 10-2022-0043608

(51) Int. Cl. H01L 33/38; H01L 25/075; H01L 33/62; H01L 33/20

(52) U.S. Cl. CPC H01L 33/382; H01L 25/0753; H01L 33/62; H01L 33/20; H01L 2933/0016; H01L 2933/0066

(57) ABSTRACT

A display device includes contact electrodes on a substrate; an interlayer insulation layer on the contact electrodes; a passivation layer on the interlayer insulation layer; pixel electrodes on the passivation layer; a first insulation layer on the pixel electrodes; light emitting elements between the pixel electrodes; and connection electrodes electrically connected to the light emitting elements, wherein the passivation layer and/or the first insulation layer include an opening exposing the interlayer insulation layer, and the connection electrodes are in contact with the contact electrodes through a contact portion penetrating the interlayer insulation layer exposed by the opening.

### CROSS-REFERENCE TO RELATED APPLICATION

This application claims priority to and the benefit of Korean Patent Application No. 10-2022-0043608 filed on Apr. 7, 2022, in the Korean Intellectual Property Office, the entire content of which is incorporated by reference herein.

### BACKGROUND

### 1. Field

The present disclosure relates to a display device and a manufacturing method thereof.

### 2. Description of the Related Art

Recently, as interest in an information display is increasing research and development for display devices are continuously conducted.

### SUMMARY

The present disclosure has been made in an effort to provide a display device and a manufacturing method thereof that may reduce or minimize contact resistance of a contact portion.

The aspects and features of embodiments of the present disclosure are not limited to the aspects and features mentioned above, and other technical aspects that are not mentioned may be clearly understood by a person of an ordinary skill in the art using the following description.

One or more embodiments of the present disclosure provide a display device including: contact electrodes on a substrate; an interlayer insulation layer on the contact electrodes; a passivation layer on the interlayer insulation layer; pixel electrodes on the passivation layer; a first insulation layer on the pixel electrodes; light emitting elements between the pixel electrodes; and connection electrodes electrically connected to the light emitting elements, wherein the passivation layer and/or the first insulation layer include an opening exposing the interlayer insulation layer, and the connection electrodes are in contact with the contact electrodes through a contact portion penetrating the interlayer insulation layer exposed by the opening.

The display device may further include a second insulation layer between the light emitting elements and the connection electrodes.

The contact portion may penetrate the second insulation layer to expose the contact electrodes.

The connection electrodes may include a first connection electrode in contact with first end portions of the light emitting elements, and a second connection electrode in contact with second end portions of the light emitting elements.

The first connection electrode may be in contact with the contact electrodes.

The display device may further include a third insulation layer between the first connection electrode and the second connection electrode.

The second insulation layer may include an opening exposing the interlayer insulation layer.

The contact portion may penetrate the third insulation layer to expose the contact electrodes.

The passivation layer may cover a first area of the interlayer insulation layer, and may include a first opening exposing a second area of the interlayer insulation layer.

A thickness of the first area of the interlayer insulation layer may be greater than a thickness of the second area thereof.

The display device may further include a via layer between the passivation layer and the electrodes.

The via layer may cover the first area of the interlayer insulation layer, and may include a second opening exposing the second area of the interlayer insulation layer.

The first insulation layer may cover the second area of the interlayer insulation layer, and may include a third opening exposing a third area of the interlayer insulation layer.

The thickness of the second area of the interlayer insulation layer may be greater than a thickness of the third area thereof.

The display device may further include a lower metal layer between the substrate and the contact electrodes, and the lower metal layer may overlap the contact portion.

Another embodiment provides a manufacturing method of a display device, including: forming contact electrodes on a substrate; forming an interlayer insulation layer on the contact electrodes; forming a passivation layer on the interlayer insulation layer; forming a first opening by etching the passivation layer; first-etching the interlayer insulation layer through the first opening of the passivation layer; forming pixel electrodes on the passivation layer; providing light emitting elements between the pixel electrodes; and forming connection electrodes on the light emitting elements; wherein the connection electrodes are in contact with the contact electrodes through a contact portion penetrating the interlayer insulation layer.

The manufacturing method of the display device may further include forming a via layer on the passivation layer; and forming a second opening by etching the via layer.

The first opening of the passivation layer and the second opening of the via layer may be concurrently formed.

The manufacturing method of the display device may further include forming a first insulation layer on the pixel electrodes; forming a third opening by etching the first insulation layer; and second-etching the interlayer insulation layer through the third opening of the first insulation layer.

The manufacturing method of the display device may further include forming a second insulation layer on the light emitting elements; forming a fourth opening by etching the second insulation layer; and forming the contact portion by third-etching the interlayer insulation layer through the fourth opening of the second insulation layer.

Particularities of other embodiments are included in the detailed description and drawings.

According to the embodiment of the present disclosure, it is possible to prevent damage to contact electrodes of a contact portion and reduce or minimize contact resistance of the contact portion, thereby improving a heat issue and luminance degradation of a display panel.

Effects, aspects, and features of embodiments of the present disclosure are not limited by what is illustrated in the above, and more various effects, aspects, and features are included in the present specification.

### BRIEF DESCRIPTION OF THE DRAWINGS

FIG. 1 illustrates a perspective view of a light emitting element according to one or more embodiments.

FIG. 2 illustrates a cross-sectional view of a light emitting element according to one or more embodiments.

FIG. 3 illustrates a top plan view of a display device according to one or more embodiments.

FIG. 4 illustrates a circuit diagram of a sub-pixel according to one or more embodiments.

FIG. 5 illustrates a top plan view of a pixel circuit area of a pixel according to one or more embodiments.

FIG. 6 illustrates a cross-sectional view taken along the line A-A′ of FIG. 5.

FIG. 7 illustrates a top plan view of a light emitting area of a pixel according to one or more embodiments.

FIG. 8 illustrates a top plan view of a sub-pixel according to one or more embodiments.

FIG. 9 illustrates a top plan view of a connection relationship between sub-electrodes of sub-pixels according to one or more embodiments.

FIG. 10 illustrates a top plan view of a connection relationship between sub-electrodes of sub-pixels according to one or more embodiments.

FIG. 11 illustrates a cross-sectional view taken along the line B-B′ of FIG. 8.

FIG. 12 illustrates a cross-sectional view of first to third sub-pixels according to one or more embodiments.

FIG. 13 illustrates a cross-sectional view of a contact portion according to one or more embodiments.

FIG. 14 illustrates a cross-sectional view of a contact portion according to one or more embodiments.

FIG. 15 to FIG. 24 illustrate cross-sectional views of process steps of a manufacturing method of a display device according to one or more embodiments.

FIG. 25 and FIG. 26 illustrate cross-sectional views of process steps of a manufacturing method of a display device according to one or more embodiments.

FIG. 27 to FIG. 31 illustrate cross-sectional views of process steps of a manufacturing method of a display device according to one or more embodiments.

### DETAILED DESCRIPTION

Aspects and features of embodiments of the present disclosure and methods of accomplishing the same may be understood more readily by reference to the following detailed description of embodiments and the accompanying drawings. The present disclosure may, however, be embodied in different forms and should not be construed as limited to the embodiments set forth herein. The present embodiments are provided so that this disclosure will be thorough and complete, and will fully convey the scope of the present disclosure to those skilled in the art, and further, the present disclosure is defined by the scope of the claims and their equivalents.

The terms used herein are for the purpose of describing particular embodiments only and is not intended to be limiting. As used herein, the singular forms “a”, “an” and “the” are intended to include the plural forms as well, unless the context clearly indicates otherwise. It will be further understood that the terms “comprise” and/or “comprising”, “include” or “including”, and “have” or “having”, when used in the present disclosure, specify the presence of stated elements, steps, operations, and/or devices, but do not preclude the presence or addition of one or more other elements, steps, operations, and/or devices.

In addition, the term “connection” or “coupling” may comprehensively mean a physical and/or electrical connection or coupling. Further, this may comprehensively mean a direct or indirect connection or coupling, and an integrated or non-integrated connection or coupling.

It will be understood that when an element or a layer is referred to as being cony another element or layer, it can be directly on another element or layer, or intervening element or layer may also be present. Throughout the specification, the same reference numerals denote the same constituent elements.

Although the terms “first”, “second”, and the like are used to describe various constituent elements, these constituent elements are not limited by these terms. These terms are used only to distinguish one constituent element from another constituent element. Therefore, the first constituent elements described below may be the second constituent elements within the technical spirit of the present disclosure.

Hereinafter, embodiments of the present disclosure will be described in detail with reference to the accompanying drawings.

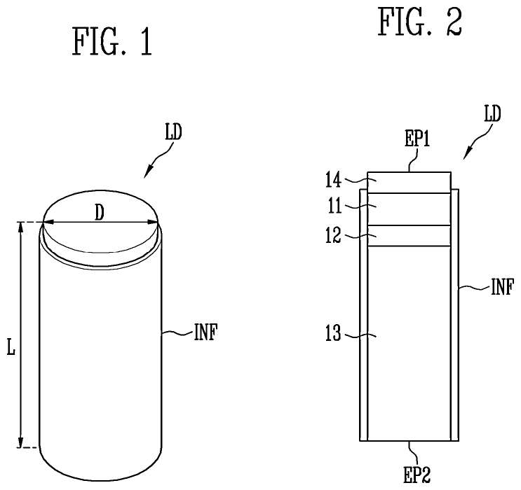

FIG. 1 illustrates a perspective view of a light emitting element according to one or more embodiments. FIG. 2 illustrates a cross-sectional view of a light emitting element according to one or more embodiments. FIG. 1 and FIG. 2 illustrate a cylindrical shape light emitting element LD, but a type and/or shape of the light emitting element LD is not limited thereto.

Referring to FIG. 1 and FIG. 2, a light emitting element LD may include a first semiconductor layer 11, an active layer 12, a second semiconductor layer 13, and/or an electrode layer 14.

The light emitting element LD may be formed to have a cylindrical shape extending along one direction. The light emitting element LD may have a first end portion EP1 and a second end portion EP2. One of the first and second semiconductor layers 11 and 13 may be disposed on the first end portion EP1 of the light emitting element LD. The remaining one of the first and second semiconductor layers 11 and 13 may be disposed on the second end portion EP2 of the light emitting element LD. For example, the first semiconductor layer 11 may be disposed on the first end portion EP1 of the light emitting element LD, and the second semiconductor layer 13 may be disposed on the second end EP2 of the light emitting element LD.

In one or more embodiments, the light emitting element LD may be a light emitting element manufactured in a cylindrical shape through an etching method or the like. In the present specification, the “cylindrical shape” includes a rod-like shape or bar-like shape with an aspect ratio greater than 1, such as a circular cylinder or a polygonal cylinder, but a shape of a cross-section thereof is not limited.

The light emitting element LD may have a size as small as a nanometer scale to a micrometer scale. For example, the light emitting element LD may each have a diameter D (or width) and/or a length L ranging from a nanometer scale to a micrometer scale. However, the size of the light emitting element LD is not limited thereto, and the size of the light emitting element LD may be variously changed according to design conditions of various devices using a light emitting device using the light emitting element LD as a light source, for example, a display device.

The first semiconductor layer 11 may be a first conductive semiconductor layer. For example, the first semiconductor layer 11 may include a p-type semiconductor layer. For example, the first semiconductor layer 11 may include at least one semiconductor material of InAlGaN, GaN, AlGaN, InGaN, and AlN, and may include a p-type semiconductor layer doped with a first conductive dopant such as Mg. However, the material included in the first semiconductor layer 11 is not limited thereto, and the first semiconductor layer 11 may be made of various materials.

The active layer 12 may be disposed between the first semiconductor layer 11 and the second semiconductor layer 13. The active layer 12 may include one of a single well structure, a multi-well structure, a single quantum well structure, a multi-quantum well (MQW) structure, a quantum dot structure, and a quantum line structure, but is not necessarily limited thereto. The active layer 12 may include GaN, InGaN, InAlGaN, AlGaN, or AlN, and in addition, it may include various other materials.

When a voltage of a threshold voltage or more is applied to respective ends of the light emitting element LD, the light emitting element LD emits light while electron-hole pairs are combined in the active layer 12. By controlling the light emitting of the light emitting element LD by using this principle, the light emitting element LD may be used as a light source for various light emitting devices in addition to pixels of a display device.

The second semiconductor layer 13 is disposed to on the active layer 12, and may include a semiconductor layer of a type different from that of the first semiconductor layer 11. The second semiconductor layer 13 may include an n-type semiconductor layer. For example, the second semiconductor layer 13 may include a semiconductor material of one of InAlGaN, GaN, AlGaN, InGaN, and AlN, and may include an n-type semiconductor layer doped with a second conductive dopant such as Si, Ge, Sn, or the like. However, the material included in the second semiconductor layer 13 is not limited thereto, and the second semiconductor layer 13 may be made of various materials.

The electrode layer 14 may be disposed on the first end portion EP1 and/or the second end portion EP2 of the light emitting element LD. FIG. 2 illustrates the case in which the electrode layer 14 is formed on the first semiconductor layer 11, but the present disclosure is not necessarily limited thereto. For example, a separate electrode layer may be further disposed on the second semiconductor layer 13.

The electrode layer 14 may include a transparent metal or transparent metal oxide. As an example, the electrode layer 14 may include at least one of an indium tin oxide (ITO), an indium zinc oxide (IZO), and a zinc tin oxide (ZTO), but is not limited thereto. As such, when the electrode layer 14 is made of the transparent metal or transparent metal oxide, light generated in the active layer 12 of the light emitting element LD may transmit through the electrode layer 14 to be emitted to the outside of the light emitting element LD.

An insulation film INF may be provided on a surface (e.g., an outer peripheral or circumferential surface) of the light emitting element LD. The insulation film INF may be directly disposed on surfaces (e.g., outer peripheral or circumferential surfaces) of the first semiconductor layer 11, the active layer 12, the second semiconductor layer 13, and/or the electrode layer 14. The insulation film INF may expose the first and second end portions EP1 and EP2 of the light emitting element LD having different polarities. In one or more embodiments, the insulation film INF may expose side portions of the electrode layer 14 and/or the second semiconductor layer 13 that are adjacent to the first and second end portions EP1 and EP2 of the light emitting element LD.

The insulation film INF may prevent an electrical short circuit that may occur when the active layer 12 contacts conductive materials other than the first and second semiconductor layers 11 and 13. In addition, the insulation film INF may reduce or minimize surface defects of the light emitting elements LD to improve lifespan and luminous efficiency of the light emitting elements LD.

The insulation film INF may include at least one of a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), and a titanium oxide (TiOx). For example, the insulation film INF may be configured as a double layer, and respective layers configuring the double layer may include different materials. For example, the insulation film INF may be formed as a double layer made of an aluminum oxide (AlOx) and a silicon oxide (SiOx), but is not limited thereto. In one or more embodiments, the insulation film INF may be omitted.

A light emitting device including the light emitting element LD described above may be used in various types of devices that require a light source in addition to a display device. For example, the light emitting elements LD may be disposed in each pixel of a display panel, and the light emitting elements LD may be used as a light source of each pixel. However, an application field of the light emitting element LD is not limited to the above-described example. For example, the light emitting element LD may be used in other types of devices that require a light source, such as a lighting device.

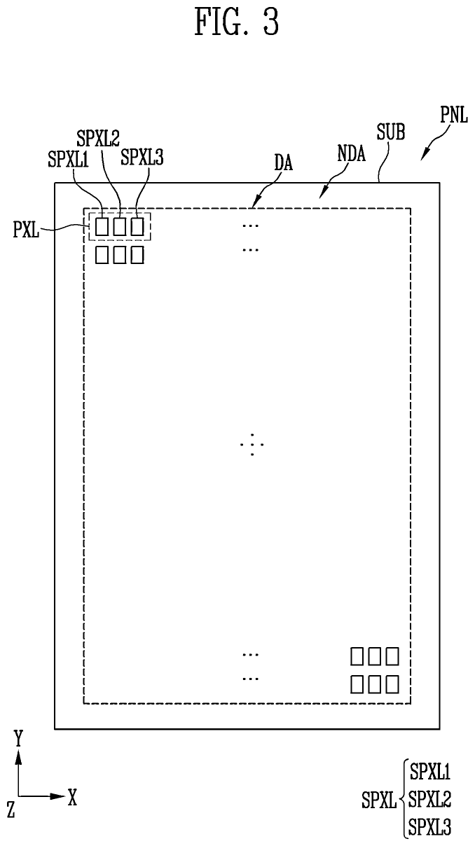

FIG. 3 illustrates a top plan view of a display device according to one or more embodiments.

FIG. 3 illustrates a display device, in particular, a display panel PNL provided in the display device as an example of an electronic device that may use the light emitting element LD described in the embodiments of FIG. 1 and FIG. 2 as a light source.

Each pixel PXL of the display panel PNL and each sub-pixel SPXL configuring the same may include at least one light emitting element LD. For better understanding and ease of description, FIG. 3 briefly illustrates a structure of the display panel PNL based on a display area DA. However, in one or more embodiments, at least one driving circuit portion (for example, at least one of a scan driver and a data driver), wires, and/or pads, may be further disposed in the display panel PNL.

Referring to FIG. 3, the display panel PNL may include a substrate SUB and the pixels PXL disposed on the substrate SUB. Each of the pixels PXL may include a first sub-pixel SPXL1, a second sub-pixel SPXL2, and/or a third sub-pixel SPXL3. Hereinafter, when arbitrarily referring to at least one of the first sub-pixel SPXL1, the second sub-pixel SPXL2, and the third sub-pixel (SPXL3), or comprehensively referring to two or more thereof, they are referred to as a “sub-pixel SPXL” or “sub-pixels SPXL”.

The substrate SUB configures a base member of the display panel PNL, and may be a rigid or flexible substrate or film. For example, the substrate SUB may be formed as a rigid substrate made of glass or tempered glass or as a flexible substrate made of a plastic or metallic material (or a thin film), but the material and/or physical properties of the substrate SUB are not particularly limited.

The display panel PNL and the substrate SUB for forming the display panel include a display area DA for displaying an image and a non-display area NDA excluding the display area DA. The pixels PXL may be disposed in the display area DA. In the non-display area NDA, various wires connected to the pixels PXL of the display area DA, pads, and/or internal circuit parts may be disposed. The pixels PXL may be regularly arranged according to a stripe or PENTILE™ arrangement structure. However, the arrangement structure of the pixels PXL is not limited thereto, and the pixels PXL may be arranged in the display area DA in various structures and/or methods. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea

In one or more embodiments, each of the pixels PXL may include two or more types of sub-pixels SPXL emitting light of different colors. For example, in the display area DA, the first sub-pixels SPXL1 emitting light of the first color, the second sub-pixels SPXL2 emitting light of the second color, and the third sub-pixels SPXL3 emitting light of the third color may be arranged. At least one first to third sub-pixels SPXL1, SPXL2, and SPXL3 disposed to be adjacent to each other may form one pixel PXL that may emit light of various colors. For example, the first sub-pixel SPXL1 may be a red pixel that emits red light, the second sub-pixel SPXL2 may be a green pixel that emits green light, and the third sub-pixel SPXL3 may be a blue pixel that emits blue light, but the present disclosure is not limited thereto.

In the described embodiment, the first sub-pixel SPXL1, the second sub-pixel SPXL2, and the third sub-pixel SPXL3 are provided with light emitting elements of the same color, and include color conversion layers and/or color filters of different colors disposed on respective light emitting elements, so that they may emit light of the first color, the second color, and the third color, respectively. In one or more embodiments, the first sub-pixel SPXL1, the second sub-pixel SPXL2, and the third sub-pixel SPXL3 are each provided with a first color light emitting element, a second color light emitting element, and a third color light emitting element as a light source, respectively, so that they respectively emit light of the first color, the second color, and the third color. However, the color, type, and/or number of the sub-pixels SPXL configuring each pixel PXL are not particularly limited.

The sub-pixel SPXL may include at least one light source driven by a suitable control signal (e.g., a predetermined control signal, such as, for example, a scan signal and a data signal) and/or a suitable power source (e.g., a predetermined power source, such as, for example, a first driving power source and a second driving power source). In the described embodiment, the light source may include at least one light emitting element LD according to one of the embodiments of FIG. 1 and FIG. 2, for example, ultra-small cylindrical shape light emitting elements LD having a size as small as nanometer scale to micrometer scale. However, the present disclosure is not limited thereto, and various types of light emitting elements LD may be used as a light source of the sub-pixel SPXL.

In the described embodiment, each sub-pixel SPXL may be configured as an active pixel. However, the type, structure, and/or driving method of the sub-pixels SPXL that may be applied to the display device are not particularly limited. For example, each sub-pixel SPXL may be configured as a pixel of a passive or active light emitting display device of various structures and/or driving methods.

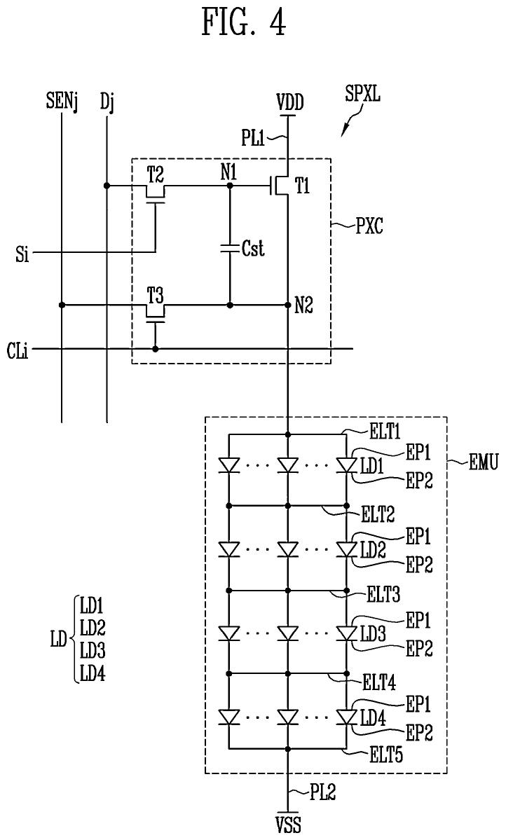

FIG. 4 illustrates a circuit diagram of a sub-pixel according to one or more embodiments.

FIG. 4 illustrates an electrical connection relationship of constituent elements included in each of the first to third sub-pixels SPXL1, SPXL2, and SPXL3 shown in FIG. 3, but the constituent elements included in each of the first to third sub-pixels SPXL1, SPXL2, and SPXL3 are not necessarily limited thereto. In addition, in FIG. 4, not only the constituent elements included in each of the first to third sub-pixels SPXL1, SPXL2, and SPXL3, but also an area in which the constituent elements are provided are comprehensively referred to as a sub-pixel SPXL.

Referring to FIG. 4, each of the first to third sub-pixels SPXL1, SPXL2, and SPXL3 may include a light emitting part EMU (or light emitting unit) that generates light of luminance in response to a data signal. In addition, the sub-pixel SPXL may further include a pixel circuit PXC for driving the light emitting part EMU.

For example, the light emitting part EMU may include a first connection electrode ELT1 connected to a first driving power source VDD through the pixel circuit PXC and a first power line PL1, a fifth connection electrode ELT5 connected to a second driving power source VSS through a second power line PL2, and a plurality of light emitting elements LD connected between the first and fifth connection electrodes ELT1 and ELT5. The first and second driving power sources VDD and VSS may have different potentials so that the light emitting elements LD may emit light. For example, the first driving power source VDD may be set as a high potential power source, and the second driving power source VSS may be set as a low potential power source.

In one or more embodiments, the light emitting part EMU may include at least one serial stage. Each serial stage may include a pair of electrodes (for example, two electrodes) and at least one light emitting element LD connected in a forward direction between the pair of electrodes. Here, the number of serial stages forming the light emitting part EMU and the number of light emitting elements LD forming each serial stage are not particularly limited. For example, the number of the light emitting elements LD configuring respective serial stages may be the same or different from each other, but the number of the light emitting elements LD is not particularly limited.

For example, the light emitting part EMU may include a first serial stage including at least one first light emitting element LD1, a second serial stage including at least one second light emitting element LD2, a third serial stage including at least one third light emitting element LD3, and a fourth serial stage including at least one fourth light emitting element LD4.

The first serial stage may include the first connection electrode ELT1, the second connection electrode ELT2, and at least one first light emitting element LD1 connected between the first and second connection electrodes ELT1 and ELT2. Each first light emitting element LD1 may be connected in a forward direction between the first and second connection electrodes ELT1 and ELT2. For example, the first end portion EP1 of the first light emitting element LD1 may be connected to the first connection electrode ELT1, and the second end portion EP2 of the first light emitting element LD1 may be connected to the second connection electrode ELT2.

The second serial stage may include the second connection electrode ELT2, a third connection electrode ELT3, and at least one second light emitting element LD2 connected between the second and third connection electrodes ELT2 and ELT3.

Each second light emitting element LD2 may be connected in a forward direction between the second and third connection electrodes ELT2 and ELT3. For example, the first end portion EP1 of the second light emitting element LD2 may be connected to the second connection electrode ELT2, and the second end portion EP2 of the second light emitting element LD2 may be connected to third connection electrode ELT3. The third serial stage may include the third connection electrode ELT3, the fourth connection electrode ELT4, and at least one third light emitting element LD3 connected between the third and fourth connection electrodes ELT3 and ELT4. Each third light emitting element LD3 may be connected in a forward direction between the third and fourth connection electrodes ELT3 and ELT4. For example, the first end portion EP1 of the third light emitting element LD3 may be connected to the third connection electrode ELT3, and the second end portion EP2 of the third light emitting element LD3 may be connected to fourth connection electrode ELT4.

The fourth serial stage may include the fourth connection electrode ELT4, the fifth connection electrode ELT5, and at least one fourth light emitting element LD4 connected between the fourth and fifth connection electrodes ELT4 and ELT5. Each fourth light emitting element LD4 may be connected in a forward direction between the fourth and fifth connection electrodes ELT4 and ELT5. For example, the first end portion EP1 of the fourth light emitting element LD4 may be connected to the fourth connection electrode ELT4, and the second end portion EP2 of the fourth light emitting element LD4 may be connected to the fifth connection electrode ELT5.

A first electrode of the light emitting part EMU, for example, the first connection electrode ELT1 may be an anode electrode of the light emitting part EMU. A last electrode of the light emitting part EMU, for example, the fifth connection electrode ELT5 may be a cathode electrode of the light emitting part EMU.

When the light emitting elements LD are connected in a serial/parallel structure, power efficiency may be improved compared with when the same number of light emitting elements LD are connected only in parallel. In addition, in the sub-pixel SPXL in which the light emitting elements LD are connected in a serial/parallel structure, even if a short circuit defect occurs at some of the serial stages, because a desirable luminance (e.g., a predetermined luminance) may be displayed through the light emitting elements LD in the remaining serial stages, the possibility of dark spot defects of the sub-pixel SPXL may be reduced. However, the present disclosure is not limited thereto, and the light emitting part EMU may be configured by connecting the light emitting elements LD only in series or only in parallel.

Each of the light emitting elements LD may include at least one electrode (for example, the first connection electrode ELT1), the first end portion EP1 (for example, a p-type end portion) connected to the first driving power source VDD via the pixel circuit PXC and/or the first power line PL1, and the second end portion EP2 (for example, an p-type end portion) connected to the second driving power source VSS via at least one other electrode (for example, the fifth connection electrode ELT5) and the second power line PL2. That is, the light emitting elements LD may be connected in a forward direction between the first driving power source VDD and the second driving power source VSS. The light emitting elements LD connected to the forward direction may configure the effective light sources of the light emitting part EMU.

When a driving current is supplied through the corresponding pixel circuit PXC, the light emitting elements LD may emit light with luminance corresponding to the driving current. For example, during each frame period, the pixel circuit PXC may supply a driving current corresponding to a gray value to be displayed in the corresponding frame to the light emitting part EMU. Accordingly, while the light emitting elements LD emit light with luminance corresponding to the driving current, the light emitting part EMU may display the luminance corresponding to the driving current.

The light emitting elements LD of the light emitting part EMU may emit light with luminance corresponding to a driving current supplied through the corresponding pixel circuit PXC. For example, during each frame period, the pixel circuit PXC may supply a driving current corresponding to a gray value of the corresponding frame to the light emitting portion EMU. The driving current supplied to the light emitting part EMU may be divided to flow in each of the light emitting elements LD. Therefore, while each light emitting element LD emits light with a luminance corresponding to the current flowing therein, the light emitting part EMU may emit light having a luminance corresponding to the driving current.

The pixel circuit PXC may be connected to a scan line Si and a data line Dj of the corresponding sub-pixel SPXL. For example, when the sub-pixel SPXL is disposed in an i-th row and a j-th column of the display area DA, the pixel circuit PXC of the sub-pixel PXL may be connected to an i-th scan line Si and a j-th data line Dj of the display area DA. In addition, the pixel circuit PXC may be connected to an i-th control line CLi and a j-th sensing line SENj of the display area DA.

The pixel circuit PXC described above may include first to third transistors T1, T2, and T3 and a storage capacitor Cst.

The first transistor T1 is a driving transistor for controlling a driving current applied to the light emitting part EMU, and may be connected between the first driving power source VDD and the light emitting part EMU. Specifically, a first terminal of the first transistor T1 may be connected to the first driving power source VDD through the first power line PL1, a second terminal of the first transistor T1 may be connected to a second node N2, and a gate electrode of the first transistor T1 may be connected to a first node N1. The first transistor T1 may control an amount of the driving current applied to the light emitting part EMU from the first driving power source VDD through the second node N2 according to a voltage applied to the first node N1. In the described embodiment, the first terminal of the first transistor T1 may be a drain electrode, and the second terminal of the first transistor T1 may be a source electrode, but the present disclosure is not limited thereto. In one or more embodiments, the first terminal thereof may be a source electrode, and the second terminal thereof may be a drain electrode.

The second transistor T2 is a switching transistor that selects the sub-pixel SPXL in response to a scan signal and activates the sub-pixel SPXL, and may be connected between the data line Dj and the first node N1. A first terminal of the second transistor T2 is connected to the data line Dj, a second terminal of the second transistor T2 is connected to the first node N1, and a gate electrode of the second transistor T2 is connected to the scan line Si. The first terminal and the second terminal of the second transistor T2 are different terminals, and for example, when the first terminal is a drain electrode, the second terminal may be a source electrode.

When a scan signal of a gate-on voltage (for example, a high level voltage) is supplied from the scan line Si, the second transistor T2 may be turned on to electrically connect the data line Dj and the first node N1. The first node N1 is a point at which the second terminal of the second transistor T2 is connected to the gate electrode of the first transistor T1, and the second transistor T2 may transmit a data voltage to the gate electrode of the first transistor T1.

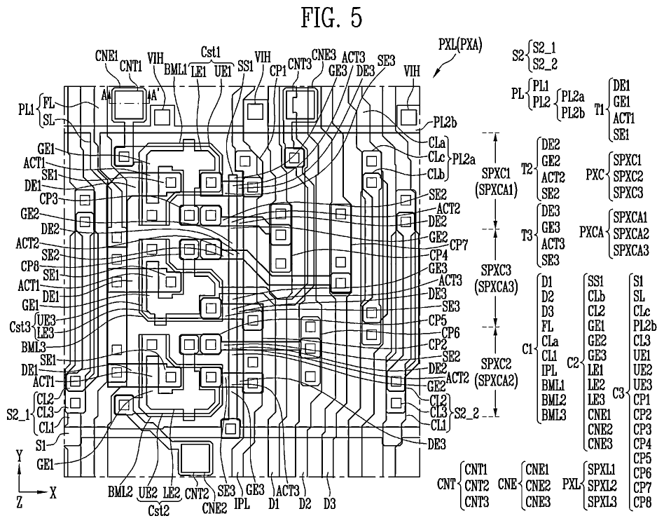

The third transistor T3 connects the first transistor T1 to the sensing line SENj, so that it may obtain a sensing signal through the sensing line SENj, and may detect a characteristic of each sub-pixel SPXL in addition to a threshold voltage of the first transistor T1 by using the sensing signal. Information on the characteristic of each sub-pixel SPXL may be used to convert image data so that a characteristic deviation between the sub-pixels SPXL may be compensated. A second terminal of the third transistor T3 may be connected to the second terminal of the first transistor T1, a first terminal of the third transistor T3 may be connected to the sensing line SENj, and a gate electrode of the third transistor T3 may be connected to the control line CLi. However, the present disclosure is not necessarily limited thereto, and as shown in FIG. 5, the gate electrode (GE3 in FIG. 5) of the third transistor T3 may be connected to the same scan line (SS1 in FIG. 5) as the gate electrode (GE2 in FIG. 5) of the second transistor T2.

In addition, the first terminal of the third transistor T3 may be connected to an initialization power source. The third transistor T3 is an initialization transistor capable of initializing the second node N2, and when a sensing control signal is supplied from the control line CLi, the third transistor T3 may be turned on to transmit a voltage of the initialization power source to the second node N2. Accordingly, a second storage electrode (or upper electrode) of the storage capacitor Cst connected to the second node N2 may be initialized.

A first storage electrode of the storage capacitor Cst may be connected to the first node N1, and the second storage electrode of the storage capacitor Cst may be connected to the second node N2. The storage capacitor Cst is charged with a voltage corresponding to the data signal supplied to the first node N1 during one frame period. Accordingly, the storage capacitor Cst may store a voltage corresponding to a difference between a voltage of the gate electrode of the first transistor T1 and a voltage of the second node N2.

FIG. 4 illustrates an embodiment in which the first to third transistors T1, T2, and T3 are all n-type transistors, but the present disclosure is not limited thereto. For example, at least one of the first to third transistors T1, T2, and T3 may be changed to a p-type transistor. In addition, although FIG. 4 discloses the embodiment in which the light emitting part EMU is connected between the pixel circuit PXC and the second driving power source VSS, the light emitting part EMU may also be connected between the first driving power source VDD and the pixel circuit PXC.

The structure of the pixel circuit PXC may be variously changed. For example, the pixel circuit PXC may additionally include other circuit elements such as at least one transistor element such as a transistor element for initializing the first node N1 and/or a transistor element for controlling a light emission time of the light emitting elements LD, or a boosting capacitor for boosting the voltage of the first node N1.

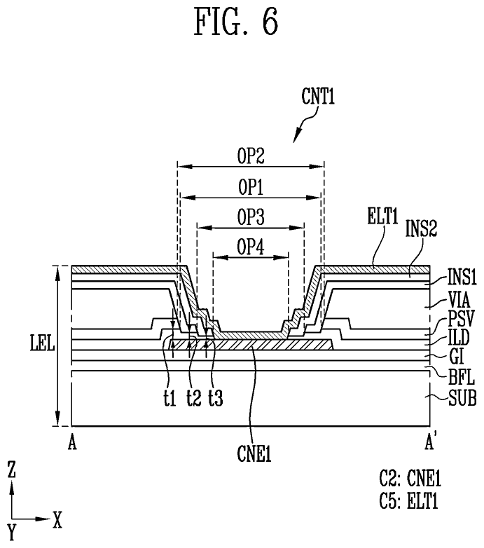

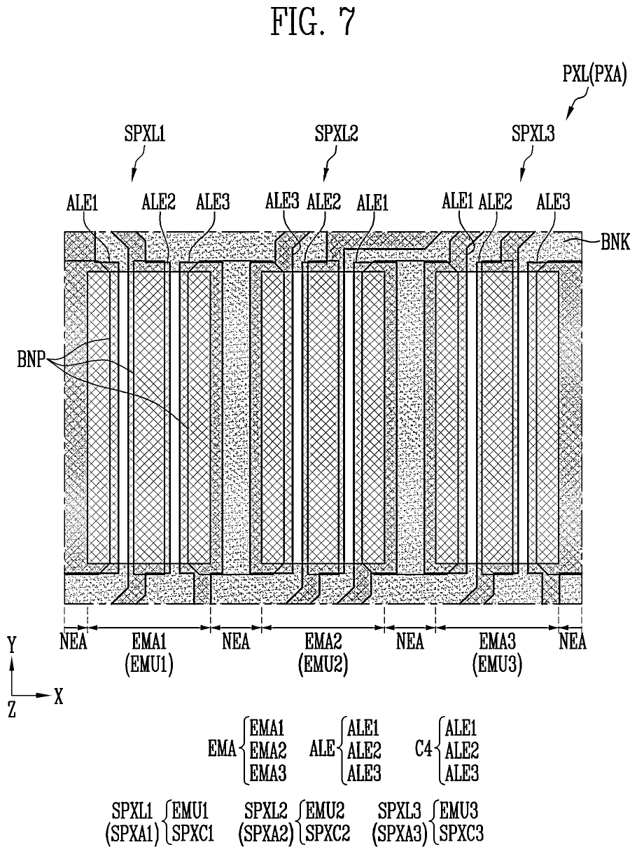

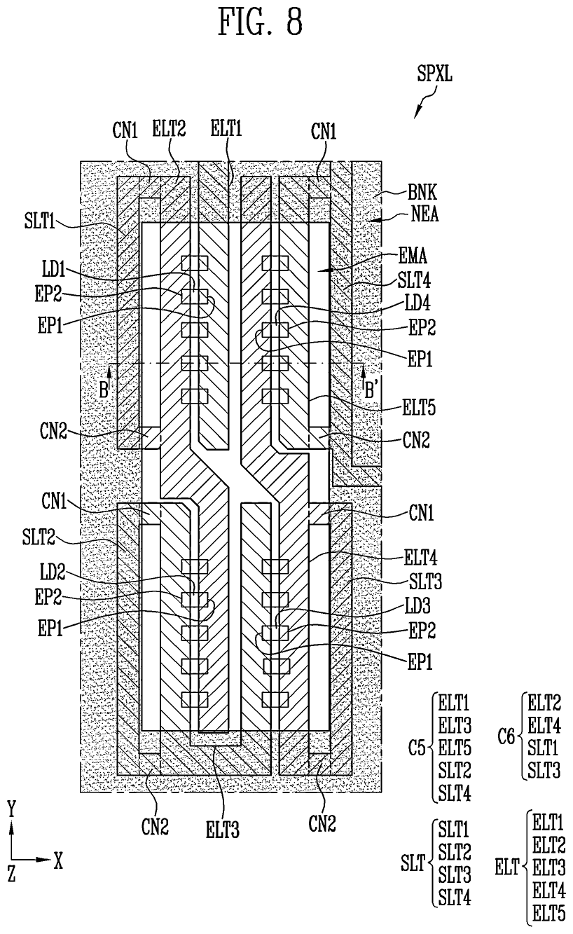

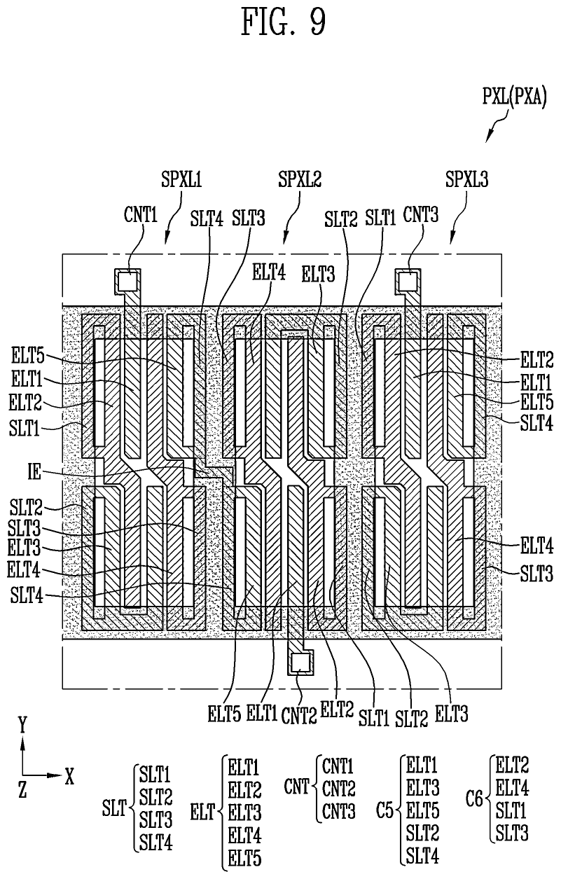

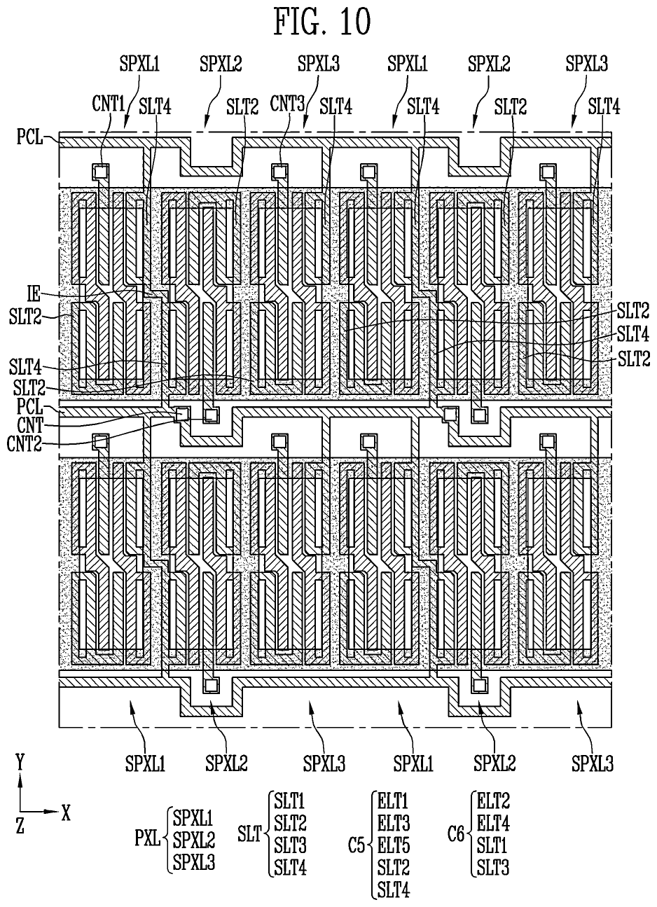

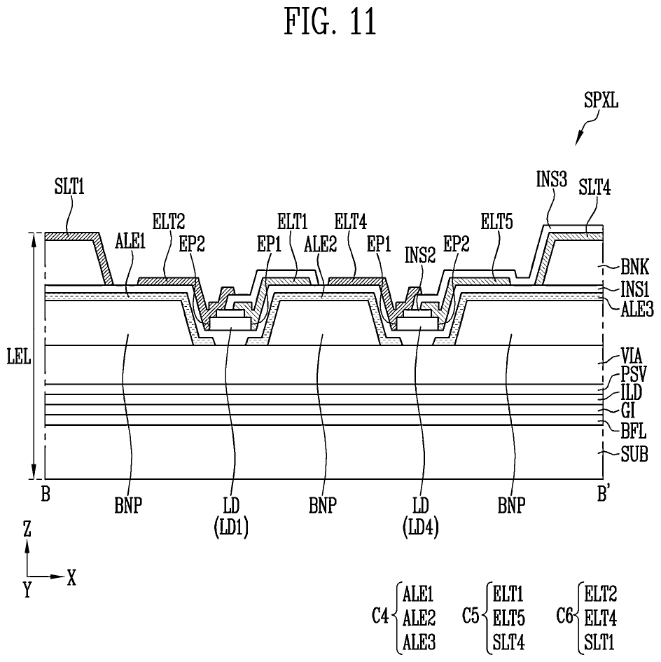

FIG. 5 illustrates a top plan view of a pixel circuit area of a pixel according to one or more embodiments. FIG. 6 illustrates a cross-sectional view taken along the line A-A′ of FIG. 5. FIG. 7 illustrates a top plan view of a light emitting area of a pixel according to one or more embodiments. FIG. 8 illustrates a top plan view of a sub-pixel according to one or more embodiments. FIG. 9 illustrates a top plan view of a connection relationship between sub-electrodes of sub-pixels according to one or more embodiments. FIG. 10 illustrates a top plan view of a connection relationship between sub-electrodes of sub-pixels according to one or more embodiments. FIG. 11 illustrates a cross-sectional view taken along the line B-B′ of FIG. 8.

Referring to FIG. 5 to FIG. 11, the pixel PXL may include a first sub-pixel SPXL1, a second sub-pixel SPXL2, and a third sub-pixel SPXL3.

The first sub-pixel SPXL1 may include a first pixel circuit SPXC1 and a first light emitting part EMU1, the second sub-pixel SPXL2 may include a second pixel circuit SPXC2 and a second light emitting part EMU2, and the third sub-pixel SPXL3 may include a third pixel circuit SPXC3 and a third light emitting part EMU3.

The first pixel circuit SPXC1, the second pixel circuit SPXC2, and the third pixel circuit SPXC3 may configure the pixel circuit PXC of the pixel PXL. The first light emitting part EMU1, the second light emitting part EMU2, and the third light emitting part EMU3 may configure the light emitting part EMU (of FIG. 4) of the pixel PXL.

One area of a pixel area PXA of the pixel PXL in which the first sub-pixel SPXL1 is provided may be a first sub-pixel area SPXA1, one area of a pixel area PXA in which the second sub-pixel SPXL2 is provided may be a second sub-pixel area SPXA2, and one area of a pixel area PXA in which the third sub-pixel SPXL3 is provided may be a third sub-pixel area SPXA3.

The pixel area PXA may include a first pixel circuit area SPXCA1, a second pixel circuit area SPXCA2, and a third pixel circuit area SPXCA3. The first pixel circuit area SPXCA1 may be an area in which the first pixel circuit SPXC1 is provided, the second pixel circuit area SPXCA2 may be an area in which the second pixel circuit SPXC2 is provided, and the third pixel circuit area SPXCA3 may be an area in which the third pixel circuit SPXC3 is provided.

The pixel area PXA may include a first light emitting area EMA1, a second light emitting area EMA2, and a third light emitting area EMA3. For example, the pixel area PXA may include the first light emitting area EMA1, the second light emitting area EMA2, and the third light emitting area EMA3 partitioned along a first direction (X-axis direction).

The first light emitting area EMA1 may be an area in which light is emitted from the light emitting elements LD driven by the first pixel circuit SPXC1. The light emitting elements LD may be one component of the first light emitting part EMU1. In the described embodiment, the first light emitting area EMA1 may be a light emitting area of the first sub-pixel SPXL1.

The second light emitting area EMA2 may be an area in which light is emitted from the light emitting elements LD driven by the second pixel circuit SPXC2. The light emitting elements LD may be one component of the second light emitting part EMU2. In the described embodiment, the second light emitting area EMA2 may be a light emitting area of the second sub-pixel SPXL2.

The third light emitting area EMA3 may be an area in which light is emitted from the light emitting elements LD driven by the third pixel circuit SPXC3. The light emitting elements LD may be one component of the third light emitting part EMU3. In the described embodiment, the third light emitting area EMA3 may be a light emitting area of the third sub-pixel SPXL3.

The first light emitting area EMA1, the second light emitting area EMA2, and the third light emitting area EMA3 described above may form the light emitting area EMA of the pixel PXL.

The pixel area PXA may include a non-light emitting area NEA adjacent to the first light emitting area EMA1 (or surrounding a periphery of the first light emitting area EMA1), a non-light emitting area NEA adjacent to the second light emitting area EMA2 (or surrounding a periphery of the second light emitting area EMA2), and a non-light emitting area NEA adjacent to the third light emitting area EMA3 (or surrounding a periphery of the third light emitting area EMA3).

A plurality of insulation layers and a plurality of conductive layers may be disposed on the substrate SUB of the pixel PXL or the pixel area PXA. The insulation layers may include, for example, a buffer layer BFL, a gate insulation layer GI, an interlayer insulation layer ILD, a passivation layer PSV, a via layer VIA, a first insulation layer INS1, a second insulation layer INS2, and/or a third insulation layer INS3 that are sequentially provided. The conductive layers may be provided and/or formed between the insulation layers described above. For example, the conductive layers may include a first conductive layer C1, a second conductive layer C2 provided on the gate insulation layer GI, a third conductive layer C3 provided on the interlayer insulation layer ILD, a fourth conductive layer C4 provided on the via layer VIA, a fifth conductive layer C5 disposed on the second insulation layer INS2, and/or a sixth conductive layer C6 disposed on the third insulation layer INS3. However, the insulation layers and the conductive layers are not limited to the above-described embodiment, and in one or more embodiments, other insulation layers and other conductive layers other than the insulation layers and the conductive layers may be provided on the substrate SUB.

Signal lines electrically connected to the pixel PXL may be formed on the substrate SUB. The signal lines may transmit a suitable signal (e.g., a predetermined signal) (or a predetermined voltage) to the pixel PXL. For example, the signal lines may include a first scan line S1, a second scan line S2, data lines D1, D2, and D3, a power line PL, and an initialization power line IPL.

A scan signal and a control signal may be selectively applied to the first scan line S1. The first scan line S1 may extend along the first direction (X-axis direction). The first scan line S1 may be formed of the third conductive layer C3. The third conductive layer C3 may be formed as a single layer or multilayer made of molybdenum (Mo), copper (Cu), aluminum (Al), chromium (Cr), gold (Au), silver (Ag), titanium (Ti), nickel (Ni), neodymium (Nd), indium (In), tin (Sn), and an oxide thereof or an alloy thereof.

The first scan line S1 may be disposed on a sub-scan line SS1 to be connected to the sub-scan line SS1 through a contact hole. For example, the first scan line S1 may be electrically connected to the sub-scan line SS1 through a contact hole penetrating the interlayer insulation layer ILD.

The sub-scan line SS1 may extend along a second direction (Y-axis direction). The sub-scan line SS1 may be formed of the second conductive layer C2. The second conductive layer C2 may be formed as a single layer or multilayer made of molybdenum (Mo), copper (Cu), chromium (Cr), gold (Au), silver (Ag), titanium (Ti), nickel (Ni), neodymium (Nd), indium (In), tin (Sn), and an oxide thereof or an alloy thereof. For example, the second conductive layer C2 may be formed as a multilayer in which titanium (Ti), copper (Cu), and/or an indium tin oxide (ITO) are sequentially or repeatedly stacked.

In the described embodiment, the sub-scan line SS1 may be provided integrally with a second gate electrode GE2 of the second transistor T2 of each of the first to third pixel circuits SPXC1, SPXC2, and SPXC3. For example, a portion of the sub-scan line SS1 may be the second gate electrode GE2 of the second transistor T2 of each of the first to third pixel circuits SPXC1, SPXC2, and SPXC3. Accordingly, the sub-scan line SS1 may be connected to the second gate electrode GE2 of the second transistor T2 of each of the first to third pixel circuits SPXC1, SPXC2, and SPXC3.

In addition, the sub-scan line SS1 may be provided integrally with a third gate electrode GE3 of the third transistor T3 of each of the first to third pixel circuits SPXC1, SPXC2, and SPXC3. For example, the other portion of the sub-scan line SS1 may be the third gate electrode GE3 of the third transistor T3 of each of the first to third pixel circuits SPXC1, SPXC2, and SPXC3. Accordingly, the sub-scan line SS1 may be connected to the third gate electrode GE3 of the third transistor T3 of each of the first to third pixel circuits SPXC1, SPXC2, and SPXC3.

As described above, as the sub-scan line SS1 is connected to the first scan line S1 through the contact hole, the first scan line S1 may be electrically connected to some components of each of the first to third pixel circuits SPXC1, SPXC2, and SPXC3, for example, the second and third transistors T2 and T3 through the sub-scan line SS1. In this case, the first scan line S1 may supply a scan signal to the second transistor T2 of each of the first to third pixel circuits SPXC1, SPXC2, and SPXC3 during a driving period of the light emitting elements LD, and may supply a control signal to the third transistor T3 of each of the first to third pixel circuits SPXC1, SPXC2, and SPXC3 during a sensing period.

The sub-scan line SS1 may be a common component commonly provided to first to third pixel circuits SPXC1, SPXC2, and SPXC3. That is, the first to third pixel circuits SPXC1, SPXC2, and SPXC3 may share one sub-scan line SS1.

The data lines D1, D2, and D3 may extend along the second direction (Y-axis direction), and may include a first data line D1, a second data line D2, and a third data line D3 spaced from each other in the first direction (X-axis direction). A data signal may be applied to each of the first to third data lines D1, D2, and D3.

The first data line D1 may be electrically connected to the second transistor T2 of the first pixel circuit SPXC1, the second data line D2 may be electrically connected to the second transistor T2 of the second pixel circuit SPXC2, and the third data line D3 may be electrically connected to the second transistor T2 of the third pixel circuit SPXC3. The first to third data lines D1, D2, and D3 may each be formed of the first conductive layer C1. The first conductive layer C1 may include the same material as the third conductive layer C3 described above, or may include at least one or more of the materials exemplified as constituent materials of the third conductive layer C3.

The power line PL may include a first power line PL1 and a second power line PL2.

A voltage of the first driving power source (VDD in FIG. 4) may be applied to the first power line PL1. The first power line PL1 may extend along the second direction (Y-axis direction). In the described embodiment, the first power line PL1 may include a first layer FL and a second layer SL. The first layer FL may be formed of the first conductive layer C1. The second layer SL may be formed of the third conductive layer C3. The second layer SL may be electrically connected to the first layer FL through at least one contact hole. For example, the second layer SL may be electrically connected to the first layer FL through at least one contact hole sequentially penetrating the buffer layer BFL, the gate insulation layer GI, and the interlayer insulation layer ILD. The first power line PL1 is implemented in a double layer structure including the first layer FL and the second layer SL to be able to reduce wire resistance to reduce signal distortion. However, the present disclosure is not necessarily limited thereto, and the first power line PL1 may be implemented in a single layer structure or a multi-layer structure of three or more layers.

A voltage of the second driving power source (VSS in FIG. 4) may be applied to the second power line PL2. The second power line PL2 may include a 2a-th power line PL2a and a 2b-th power line PL2b.

The 2a-th power line PL2a may extend along the second direction (Y-axis direction). The 2a-th power line PL2a may include a first layer CLa, a second layer CLb, and a third layer CLc. The first layer CLa may be formed of the first conductive layer C1, the second layer CLb may be formed of the second conductive layer C2, and the third layer CLc may be formed of the third conductive layer C3.

The first layer CLa, the second layer CLb, and the third layer CLc may overlap each other. The first to third layers CLa, CLb, and CLc may be electrically connected to each other through at least one contact hole. For example, the third layer CLc may be electrically connected to the first layer CLa through a contact hole sequentially penetrating the buffer layer BFL, the gate insulation layer GI, and the interlayer insulation layer ILD. In addition, the third layer CLc may be electrically connected to the second layer CLb through a contact hole penetrating the interlayer insulation layer ILD. Accordingly, the first layer CLa and the second layer CLb may be electrically connected to each other through the third layer CLc.

In the above-described embodiment, the embodiment in which the 2a-th power line PL2a is implemented in a triple-layer structure has been described, but the present disclosure is not limited thereto. In one or more embodiments, the 2a-th power line PL2a may be implemented in a double layer structure similar to the first power line PL1.

The 2b-th power line PL2b may extend along the first direction (X-axis direction). The 2b-th power line PL2b may be implemented in a single layer structure. The 2b-th power line PL2b may be formed of the third conductive layer C3. The 2b-th power line PL2b may be electrically connected to at least one of electrodes ALE of the first to third sub-pixel areas SPXA1, SPXA2, and SPXA3 to be described later through via holes VIH. The electrodes ALE may receive a suitable alignment signal (e.g., a predetermined alignment signal) through the via holes VIH, but are not limited thereto.

The 2a-th power line PL2a and the 2b-th power line PL2b may be electrically connected through a contact hole. As an example, the 2b-th power line PL2b may be electrically connected to the 2a-th power line PL2a through a contact hole sequentially penetrating the buffer layer BFL, the gate insulation layer GI, and the interlayer insulation layer ILD. The second power line PL2 including the 2a-th power line PL2a and the 2b-th power line PL2b that are connected to each other may have a mesh structure.

The second scan line S2 may extend in the second direction (Y-axis direction) crossing the first direction (X-axis direction) which is an extension direction of the first scan line S1. In the pixel PXL, the second scan line S2 may cross the first scan line S1 to at least partially overlap the first scan line S1. The second scan line S2 may be a signal line that selectively receives a scan signal and a control signal. For example, the second scan line S2 may be supplied with a scan signal during a driving period of the light emitting elements LD, and may be supplied with a control signal during a suitable sensing period (e.g., a predetermined sensing period).

In the described embodiment, the second scan line S2 may include a (2-1)-th scan line S2_1 and a (2-2)-th scan line S2_2. Each of the (2-1)-th scan line S2_1 and the (2-2)-th scan line S2_2 may extend along the second direction (Y-axis direction).

Each of the (2-1)-th scan line S2_1 and the (2-2)-th scan line S2_2 may be implemented in a triple layer structure including a first conductive line CL1, a second conductive line CL2, and a third conductive line CL3. The first conductive line CL1 may be formed of the first conductive layer C1, the second conductive line CL2 may be formed of the second conductive layer C2, and the third conductive line CL3 may be formed of the third conductive layer C3.

The first conductive line CL1, the second conductive line CL2, and the third conductive line CL3 may overlap each other. The third conductive line CL3 may be electrically connected to the first conductive line CL1 through a contact hole sequentially penetrating the buffer layer BFL, the gate insulation layer GI, and the interlayer insulation layer ILD. In addition, the third conductive line CL3 may be electrically connected to the second conductive line CL2 through a contact hole penetrating the interlayer insulation layer ILD. Accordingly, the first conductive line CL1 and the second conductive line CL2 may be electrically connected to each other through the third conductive line CL3.

In the embodiment described above, it has been described that the (2-1)-th scan line S2_1 and the (2-2)-th scan line S2_2 are implemented in a triple layer structure including the first conductive line CL1, the second conductive line CL2, and the third conductive line CL3, but the present disclosure is not limited thereto. In one or more embodiments, the (2-1)-th scan line S2_1 and the (2-2)-th scan line S2_2 may be implemented as a single layer structure, a double layer structure, or a multi-layer structure of three or more layers.

In one or more embodiments, the first conductive line CL1 of each of the (2-1)-th and (2-2)-th scan lines S2_1 and S2_2 may be commonly provided in some of the pixels PXL disposed in the same pixel column in the second direction (Y-axis direction). For example, the first conductive line CL1 of each of the (2-1)-th and (2-2)-th scan lines S2_1 and S2_2 of the pixel PXL may be commonly provided in the pixels PXL disposed in the same pixel column in the second direction (Y-axis direction). That is, the pixels PXL disposed in the same pixel column in the second direction (Y-axis direction) may share the first conductive line CL1 of each of the (2-1)-th and (2-2)-th scan lines S2_1 and S2_2.

At least one of the (2-1)-th scan line S2_1 and the (2-2)-th scan line S2_2 may be connected to the first scan line S1 through a contact hole. For example, the (2-1)-th scan line S2_1 may be electrically connected to the first scan line S1 through a contact hole sequentially passing through at least one insulation layer, for example, the buffer layer BFL, the gate insulation layer GI, and the interlayer insulation layer ILD. Accordingly, the first scan line S1 may selectively receive a scan signal and a control signal from the (2-1)-th scan line S2_1. That is, the second scan line S2 may be used as a signal line that may be connected to the first scan line S1 to transmit a scan signal and a control signal together with the first scan line S1 to some components of each of the first to third pixel circuits SPXC1, SPXC2, and SPXC3, for example, the second and third transistors T2 and T3.

The initialization power line IPL may extend along the second direction (Y-axis direction). The initialization power line IPL may be the j-th sensing line SENj described with reference to FIG. 4. A voltage of the initialization power source may be applied to the initialization power line IPL. In the described embodiment, the initialization power line IPL may be formed of the first conductive layer C1.

The initialization power line IPL may be electrically connected to the third transistor T3 of the first pixel circuit SPXC1 through a first conductive pattern CP1, may be electrically connected to the third transistor T3 of the second pixel circuit SPXC2 through a second conductive pattern CP2, and may be electrically connected to the third transistor T3 of the third pixel circuit SPXC3 through a third conductive pattern CP3.

The first conductive pattern CP1 may be formed of the third conductive layer C3. One end of the first conductive pattern CP1 may be connected to the initialization power line IPL through a contact hole. As an example, one end of the first conductive pattern CP1 may be electrically connected to the initialization power line IPL through a contact hole sequentially penetrating the buffer layer BFL, the gate insulation layer GI, and the interlayer insulation layer ILD.

The other end of the first conductive pattern CP1 may be connected to the third transistor T3 of the first pixel circuit SPXC1 through another contact hole. For example, the other end of the first conductive pattern CP1 may be electrically connected to a third drain area DE3 of the third transistor T3 of the first pixel circuit SPXC1 through a contact hole sequentially penetrating the gate insulation layer GI and the interlayer insulation layer ILD.

The second conductive pattern CP2 may be formed of the third conductive layer C3. The second conductive pattern CP2 may be connected to the initialization power line IPL through a contact hole. As an example, the second conductive pattern CP2 may be electrically connected to the initialization power line IPL through a contact hole sequentially penetrating the buffer layer BFL, the gate insulation layer GI, and the interlayer insulation layer ILD.

The second conductive pattern CP2 may be connected to the third transistor T3 of the second pixel circuit SPXC2 through another contact hole. For example, the second conductive pattern CP2 may be electrically connected to a third drain area DE3 of the third transistor T3 of the second pixel circuit SPXC2 through a contact hole sequentially penetrating the gate insulation layer GI and the interlayer insulation layer ILD.

The second conductive pattern CP2 may be connected to the third transistor T3 of the third pixel circuit SPXC3 through another contact hole. For example, the second conductive pattern CP2 may be electrically connected to a third drain area DE3 of the third transistor T3 of the third pixel circuit SPXC3 through a contact hole sequentially penetrating the gate insulation layer GI and the interlayer insulation layer ILD.

The first power line PL1, the second power line PL2, the initialization power line IPL, the sub-scan line SS1, the first scan line S1, and the second scan line S2 described above may be common components commonly provided to the first to third pixel circuits SPXC1, SPXC2, and SPXC3.

Each of the first to third pixel circuits SPXC1, SPXC2, and SPXC3 may include the first transistor T1, the second transistor T2, the third transistor T3, and the storage capacitor. For example, the first pixel circuit SPXC1 may include the first to third transistors T1, T2, and T3, and the first storage capacitor Cst1. The second pixel circuit SPXC2 may include the first to third transistors T1, T2, and T3, and a second storage capacitor Cst2. The third pixel circuit SPXC3 may include the first to third transistors T1, T2, and T3, and the third storage capacitor Cst3.

The first transistor T1 of each of the first to third pixel circuits SPXC1, SPXC2, and SPXC3 may be the first transistor T1 described with reference to FIG. 4, and the second transistor T2 of each of the first to third pixel circuits SPXC1, SPXC2, and SPXC3 may be the second transistor T2 described with reference to FIG. 4, and the third transistor T3 of each of the first to third pixel circuits SPXC1, SPXC2, and SPXC3 may be the third transistor T3 described with reference to FIG. 4.

The first to third pixel circuits SPXC1, SPXC2, and SPXC3 may have a substantially similar or the same structure. Hereinafter, the first pixel circuit SPXC1 from among the first to third pixel circuits SPXC1, SPXC2, and SPXC3 will be described as a representative, and the second and third pixel circuits SPXC2 and SPXC3 will be briefly described.

The first pixel circuit SPXC1 includes the first transistor T1, the second transistor T2, the third transistor T3, and the first storage capacitor Cst1.

The first transistor T1 may include a first gate electrode GE1, a first active pattern ACT1, a first source area SE1, and a first drain area DE1.

The first gate electrode GE1 may be electrically connected to a second source area SE2 of the second transistor T2 through the third conductive pattern CP3. The first gate electrode GE1 may be formed of the second conductive layer C2.

The third conductive pattern CP3 may be formed of the third conductive layer C3. One end of the third conductive pattern CP3 may be connected to the first gate electrode GE1 through a contact hole. For example, one end of the third conductive pattern CP3 may be electrically connected to the first gate electrode GE1 through a contact hole penetrating the interlayer insulation layer ILD. The other end of the third conductive pattern CP3 may be connected to the second source area SE2 through another contact hole. As an example, the other end of the third conductive pattern CP3 may be electrically connected to the second source area SE2 through a contact hole sequentially penetrating the gate insulation layer GI and the interlayer insulation layer ILD.

The first active pattern ACT1, the first source area SE1, and the first drain area DE1 may be semiconductor patterns made of a polysilicon, an amorphous silicon, an oxide semiconductor, or the like. The first active pattern ACT1, the first source area SE1, and the first drain area DE1 may be formed as a semiconductor layer in which no impurity is doped or an impurity is doped. For example, the first source area SE1 and the first drain area DE1 may be formed as a semiconductor layer in which an impurity is doped, and the first active pattern ACT1 may be formed as a semiconductor layer in which no impurity is doped.

The first active pattern ACT1, the first source area SE1, and the first drain area DE1 may be provided and/or formed on the buffer layer.

The first active pattern ACT1 is an area overlapping the first gate electrode GE1, and may be a channel area of the first transistor T1. When the first active pattern ACT1 is formed to be long, the channel area of the first transistor T1 may be formed to be long. In this case, a driving range of a suitable voltage (e.g., a predetermined voltage) applied to the first transistor T1 may be widened. Accordingly, it is possible to finely control a grayscale of light emitted from the light emitting elements LD.

The first source area SE1 may be connected to (or may contact) one end of the first active pattern ACT1. In addition, the first source area SE1 may be electrically connected to a first lower metal layer BML1 through a contact hole penetrating the buffer layer BFL.

The first lower metal layer BML1 may be formed of the first conductive layer C1. The first lower metal layer BML1 may be electrically connected to the first source area SE1 through a contact hole. When the first lower metal layer BML1 is connected to the first transistor T1, a swing width margin of the second driving power source VSS may be further secured. In this case, a driving range of a suitable voltage (e.g., a predetermined voltage) supplied to the first gate electrode GE1 of the first transistor T1 may be widened.

The first drain area DE1 may be connected to (or may contact) the other end of the first active pattern ACT1. In addition, the first drain area DE1 may be connected to the first power line PL1 through a contact hole. For example, in one or more embodiments, the first drain area DE1 may be electrically connected to the first layer FL of the first power line PL1 through a contact hole penetrating the buffer layer BFL.

The second transistor T2 may include a second gate electrode GE2, a second active pattern ACT2, a second source area SE2, and a second drain area DE2.

The second gate electrode GE2 may be provided integrally with the sub-scan line SS1. In this case, the second gate electrode GE2 may be one area of the sub-scan line SS1. As described above, because the sub-scan line SS1 is electrically connected to the first scan line S1 through the contact hole, a suitable signal (e.g., a predetermined signal, such as, for example, a scan signal) applied to the first scan line S1 may be finally supplied to the second gate electrode GE2.

The second active pattern ACT2, the second source area SE2, and the second drain area DE2 may be semiconductor patterns made of polysilicon, an amorphous silicon, an oxide semiconductor, or the like. The second active pattern ACT2, the second source area SE2, and the second drain area DE2 may be formed as a semiconductor layer in which no impurity is doped or an impurity is doped. For example, the second source area SE2 and the second drain area DE2 may be formed as a semiconductor layer in which an impurity is doped, and the second active pattern ACT2 may be formed as a semiconductor layer in which no impurity is doped. The second active pattern ACT2, the second source area SE2, and the second drain area DE2 may be provided and/or formed on the buffer layer BFL.

The second active pattern ACT2 is an area overlapping the second gate electrode GE2, and may be a channel area of the second transistor T2.

The second source area SE2 may be connected to (or may contact) one end of the second active pattern ACT2. In addition, the second source area SE2 may be connected to the first gate electrode GE1 through the third conductive pattern CP3.

The second drain area DE2 may be connected to (or may contact) the other end of the second active pattern ACT2. In addition, the second drain area DE2 may be connected to the first data line D1 through a fourth conductive pattern CP4.

The fourth conductive pattern CP4 may be the third conductive layer C3. One end of the fourth conductive pattern CP4 may be electrically connected to the first data line D1 through a contact hole sequentially penetrating the buffer layer BFL, the gate insulation layer GI, and the interlayer insulation layer ILD. The other end of the fourth conductive pattern CP4 may be connected to the second drain area DE2 through a contact hole sequentially penetrating the gate insulation layer GI and the interlayer insulation layer ILD. The second drain area DE2 and the first data line D1 may be electrically connected through the fourth conductive pattern CP4.

The third transistor T3 may include a third gate electrode GE3, a third active pattern ACT3, a third source area SE3, and a third drain area DE3.

The third gate electrode GE3 may be provided integrally with the sub-scan line SS1. In this case, the third gate electrode GE3 may be the other one area of the sub-scan line SS1. As described above, because the sub-scan line SS1 is connected to the first scan line S1 through the contact hole, a suitable signal (e.g., a predetermined signal, such as, for example, a control signal) applied to the first scan line S1 may be finally supplied to the third gate electrode GE3.

The third active pattern ACT3, the third source area SE3, and the third drain area DE3 may be semiconductor patterns made of polysilicon, an amorphous silicon, an oxide semiconductor, or the like. The third active pattern ACT3, the third source area SE3, and the third drain area DE3 may be formed as a semiconductor layer in which no impurity is doped or an impurity is doped. For example, the third source area SE3 and the third drain area DE3 may be formed as a semiconductor layer in which an impurity is doped, and the third active pattern ACT3 may be formed as a semiconductor layer in which no impurity is doped.

The third active pattern ACT3, the third source area SE3, and the third drain area DE3 may be provided and/or formed on the buffer layer.

The third active pattern ACT3 is an area overlapping the third gate electrode GE3, and may be a channel area of the third transistor T3.

The third source area SE3 may be connected to (or may contact) one end of the third active pattern ACT3. In addition, the third source area SE3 may be electrically connected to a first lower metal layer BML1 through a contact hole penetrating the buffer layer BFL.

The third drain area DE3 may be connected to (or may contact) the other end of the third active pattern ACT3. In addition, the third drain area DE3 may be electrically connected to the initialization power line IPL through the first conductive pattern CP1.

The first storage capacitor Cst1 may include a first lower electrode LE1 and a first upper electrode UE1. Here, the first storage capacitor Cst1 may be the storage capacitor Cst described with reference to FIG. 4.

The first lower electrode LE1 may be provided integrally with the first gate electrode GE1. In this case, the first lower electrode LE1 may be one area of the first gate electrode GE1. The first lower electrode LE1 may be formed of the second conductive layer C2.

The first upper electrode UE1 may be disposes to overlap the first lower electrode LE1 in a plan view, and may have a larger size (or area) than the first lower electrode LE1, but is not limited thereto. The first upper electrode UE1 may overlap each of the first source area SE1 and the third source area SE3 in a plan view. The first upper electrode UE1 may be formed of the third conductive layer C3.

The first upper electrode UE1 may be electrically connected to the first lower metal layer BML1 through a contact hole sequentially penetrating the buffer layer BFL, the gate insulation layer GI, and the interlayer insulation layer ILD. As described above, because the first source area SE1 and the third source area SE3 are electrically connected to the first lower metal layer BML1, the first upper electrode UE1 may be electrically connected to the first and third source areas SE1 and SE3 through the first lower metal layer BML1.

The second pixel circuit SPXC2 may include the first transistor T1, the second transistor T2, the third transistor T3, and the second storage capacitor Cst2.

The first transistor T1 may include a first gate electrode GE1, a first active pattern ACT1, a first source area SE1, and a first drain area DE1.

The first gate electrode GE1 may be connected to the second source area SE2 of the second transistor T2.

The first active pattern ACT1 may be a channel area of the first transistor T1.

The first source area SE1 may be connected to the first active pattern ACT1. In addition, the first source area SE1 may be electrically connected to a second lower metal layer BML2 through a contact hole penetrating the buffer layer BFL.

The second lower metal layer BML2 may correspond to the first lower metal layer BML1. The second lower metal layer BML2 may be formed of the first conductive layer C1. The second lower metal layer BML2 may be electrically connected to the first source area SE1 through a contact hole. In addition, the second lower metal layer BML2 may be electrically connected to the third source area SE3 of the third transistor T3 through another contact hole penetrating the buffer layer BFL. Additionally, the second lower metal layer BML2 may be electrically connected to the second upper electrode UE2 through another contact hole sequentially penetrating the buffer layer BFL, the gate insulation layer GI, and the interlayer insulation layer ILD.

The first drain area DE1 may be connected to the first active pattern ACT1. In addition, the first drain area DE1 may be electrically connected to the first layer FL of the first power line PL1 through another contact hole penetrating the buffer layer BFL.

The second transistor T2 may include a second gate electrode GE2, a second active pattern ACT2, a second source area SE2, and a second drain area DE2.

The second gate electrode GE2 is provided integrally with the sub-scan line SS1, and may be connected to the first scan line S1. The second gate electrode GE2 may be formed of the second conductive layer C2.

The second active pattern ACT2 may be a channel area of the second transistor T2.

The second source area SE2 may be connected to the second active pattern ACT2. In addition, the second source area SE2 may be connected to the first gate electrode GE1 through the fifth conductive pattern CP5.

The fifth conductive pattern CP5 may be formed of the third conductive layer C3. One end of the fifth conductive pattern CP5 may be electrically connected to the second source area SE2 through a contact hole sequentially penetrating the gate insulation layer GI and the interlayer insulation layer ILD. The other end of the fifth conductive pattern CP5 may be connected to the first gate electrode GE1 through a contact hole penetrating the interlayer insulation layer ILD.

The second drain area DE2 may be connected to the second active pattern ACT2. In addition, the second drain area DE2 may be connected to the second data line D2 through a sixth conductive pattern CP6.

The sixth conductive pattern CP6 may be the third conductive layer C3. One end of the sixth conductive pattern CP6 may be electrically to the to the second data line D2 through a contact hole sequentially penetrating the buffer layer BFL, the gate insulation layer GI, and the interlayer insulation layer ILD. The other end of the sixth conductive pattern CP6 may be electrically connected to the second drain area DE2 through a contact hole sequentially penetrating the gate insulation layer GI and the interlayer insulation layer ILD.

The third transistor T3 may include a third gate electrode GE3, a third active pattern ACT3, a third source area SE3, and a third drain area DE3.

The third gate electrode GE3 is provided integrally with the sub-scan line SS1, and may be connected to the first scan line S1. The third gate electrode GE3 may be formed of the second conductive layer C2.

The third active pattern ACT3 may be a channel area of the third transistor T3.

The third source area SE3 may be electrically connected to the third active pattern ACT3. In addition, the third source area SE3 may be electrically connected to the second lower metal layer BML2 through a contact hole.

The third drain area DE3 may be connected to the third active pattern ACT3. In addition, the third drain area DE3 may be connected to the initialization power line IPL through the second conductive pattern CP2.

The second storage capacitor Cst2 may have the same structure as or a substantially similar structure to that of the first storage capacitor Cst1 of the first pixel circuit SPXC1 described above. For example, the second storage capacitor Cst may include the second lower electrode LE2 and the second upper electrode UE2.

The second lower electrode LE2 may be formed of the second conductive layer C2, and may be provided integrally with the first gate electrode GE1 of the second transistor T2. The second upper electrode UE2 may be formed of the third conductive layer C3, and may overlap the second lower electrode LE2. The second upper electrode UE2 may be electrically connected to the second lower metal layer BML2 through a contact hole.

As described above, the second upper electrode UE2 may be electrically connected to each of the first source area SE1 and the third source area SE3 through the second lower metal layer BML2.

The third pixel circuit SPXC3 may include the first transistor T1, the second transistor T2, the third transistor T3, and the third storage capacitor Cst3.

The first transistor T1 may include a first gate electrode GE1, a first active pattern ACT1, a first source area SE1, and a first drain area DE1.

The first gate electrode GE1 may be connected to the third source area SE3 of the third transistor T3. The first gate electrode GE1 may be formed of the second conductive layer C2.

The first active pattern ACT1 may be a channel area of the first transistor T1.

The first source area SE1 may be connected to the first active pattern ACT1. In addition, the first source area SE1 may be electrically connected to a third lower metal layer BML3 through a contact hole penetrating the buffer layer BFL.

The third lower metal layer BML3 may have a configuration corresponding to each of the first and second lower metal layers BML1 and BML2. The third lower metal layer BML3 may be formed of the first conductive layer C1. The third lower metal layer BML3 may be electrically connected to the first source area SE1 through a contact hole. In addition, the third lower metal layer BML3 may be electrically connected to the third source area SE3 of the third transistor T3 through another contact hole penetrating the buffer layer. Additionally, the third lower metal layer BML3 may be electrically connected to the third upper electrode UE3 through another contact hole sequentially penetrating the buffer layer BFL, the gate insulation layer GI, and the interlayer insulation layer ILD.

The first drain area DE1 may be connected to the first active pattern ACT1. In addition, the first drain area DE1 may be electrically connected to the first layer FL of the first power line PL1 through another contact hole penetrating the buffer layer BFL.

The second transistor T2 may include a second gate electrode GE2, a second active pattern ACT2, a second source area SE2, and a second drain area DE2.

The second gate electrode GE2 may be provided integrally with the sub-scan line SS1 to be connected to the first scan line S1. The second gate electrode GE2 may be formed of the second conductive layer C2.

The second active pattern ACT2 may be a channel area of the second transistor T2.

The second source area SE2 may be connected to the second active pattern ACT2. In addition, the second source area SE2 may be electrically connected to the third lower metal layer BML3 through a contact hole.

The second drain area DE2 may be connected to the second active pattern ACT2. In addition, the second drain area DE2 may be connected to the third data line D3 through a seventh conductive pattern CP7.

The seventh conductive pattern CP7 may be formed of the third conductive layer C3. One end of the seventh conductive pattern CP7 may be electrically to the to the third data line D3 through a contact hole sequentially penetrating the buffer layer BFL, the gate insulation layer GI, and the interlayer insulation layer ILD. The other end of the seventh conductive pattern CP7 may be electrically connected to the second drain area DE2 through a contact hole sequentially penetrating the gate insulation layer GI and the interlayer insulation layer ILD. Accordingly, the second drain area DE2 and the third data line D3 may be connected to each other through the seventh conductive pattern CP7.

The third transistor T3 may include a third gate electrode GE3, a third active pattern ACT3, a third source area SE3, and a third drain area DE3.

The third gate electrode GE3 is provided integrally with the sub-scan line SS1, and may be connected to the first scan line S1.

The third active pattern ACT3 may be a channel area of the third transistor T3.

The third source area SE3 may be connected to the third active pattern ACT3. In addition, the third source area SE3 may be connected to the first gate electrode GE1 through an eighth conductive pattern CP8.

The eighth conductive pattern CP8 may be formed of the third conductive layer C3. One end of the eighth conductive pattern CP8 may be electrically connected to the third source area SE3 through a contact hole sequentially penetrating the gate insulation layer GI and the interlayer insulation layer ILD. The other end of the eighth conductive pattern CP8 may be connected to the first gate electrode GE1 through a contact hole penetrating the interlayer insulation layer ILD. Accordingly, the first gate electrode GE1 and the third source area SE3 may be connected to each other through the eighth conductive pattern CP8.

The third drain area DE3 may be connected to the third active pattern ACT3. In addition, the third drain area DE3 may be connected to the initialization power line IPL through the eighth conductive pattern CP8. In the described embodiment, the third drain area DE3 of the third transistor T3 and the second drain area DE2 of the second transistor T2 may share the eighth conductive pattern CP8.

The third storage capacitor Cst3 may have the same structure as or a substantially similar structure to that of each of the first and second storage capacitors Cst1 and Cst2 described above. For example, the third storage capacitor Cst3 may include a third lower electrode LE3 and a third upper electrode UE3.

The third lower electrode LE3 may be formed of the second conductive layer C2, and may be provided integrally with the first gate electrode GE1 of the corresponding transistor, for example, the first transistor T1. The third upper electrode UE3 may be formed of the third conductive layer C3, and may overlap the third lower electrode LE3. The third upper electrode UE3 may be electrically connected to the third lower metal layer BML3 through a contact hole. As described above, the third upper electrode UE3 may be electrically connected to each of the first source area SE1 and the third source area SE3 through the third lower metal layer BML3.

The first pixel circuit SPXC1 described above may be electrically connected to the first light emitting part EMU1. For example, the first light emitting part EMU1 may be electrically connected to a first contact electrode CNE1 through a first contact portion CNT1, and may be electrically connected to the first upper electrode UE1 of the first storage capacitor Cst1 through the first contact electrode CNE1. For example, the first connection electrode ELT1 of the first light emitting part EMU1 may be electrically connected to the first contact electrode CNE1 through the first contact portion CNT1.

The second pixel circuit SPXC2 may be electrically connected to the second light emitting part EMU2. For example, the second light emitting part EMU2 may be electrically connected to a second contact electrode CNE2 through a second contact portion CNT2, and may be electrically connected to the second upper electrode UE2 of the second storage capacitor Cst2 through the second contact electrode CNE2. For example, the first connection electrode ELT1 of the second light emitting part EMU2 may be electrically connected to the second contact electrode CNE2 through the second contact portion CNT2.

The third pixel circuit SPXC3 may be electrically connected to the third light emitting part EMU3. For example, the third light emitting part EMU3 may be electrically connected to a third contact electrode CNE3 through a third contact portion CNT3, and may be electrically connected to the third upper electrode UE3 of the third storage capacitor Cst3 through the third contact electrode CNE3. For example, the first connection electrode ELT1 of the third light emitting part EMU3 may be electrically connected to the third contact electrode CNE3 through the third contact portion CNT3.

Each of the first to third the contact electrodes CNE1, CNE2, and CNE3 may be formed of the second conductive layer C2. For example, each of the first to third contact electrodes CNE1, CNE2, and CNE3 may be formed as a multi-layer in which titanium (Ti), copper (Cu), and/or an indium tin oxide (ITO) are sequentially or repeatedly stacked. In this case, because contact resistance due to an oxide film (for example, an aluminum oxide film) may be improved, a heat issue of the contact portion CNT and luminance degradation of the display panel PNL may be improved.

The first to third contact portions CNT1, CNT2, and CNT3 may have substantially similar or identical structure. Hereinafter, the first contact portion CNT1 from among the first to third contact portions CNT1, CNT2, and CNT3 will be representatively described, and the second and third contact portions CNT2 and CNT3 will be briefly described.

As shown in FIG. 6, the interlayer insulation layer ILD may be disposed on the first contact electrode CNE1. The passivation layer PSV may be disposed on the interlayer insulation layer ILD. The passivation layer PSV may cover a first area of the interlayer insulation layer ILD. The passivation layer PSV may include a first opening OP1 exposing a second area of the interlayer insulation layer ILD. The first opening OP1 of the passivation layer PSV may overlap the first contact portion CNT1.

In a process of forming the first opening OP1 of the passivation layer PSV, the second area of the interlayer insulation layer ILD may be partially etched. Accordingly, a thickness t2 in a third direction (Z-axis direction) of the second area of the interlayer insulation layer (ILD) may be smaller than a thickness t1 in the third direction (Z-axis direction) of the first area of the interlayer insulation layer ILD, but is not limited thereto.

The via layer VIA may be disposed on the passivation layer PSV. The via layer VIA may cover the first area of the interlayer insulation layer ILD. The via layer VIA may include a second opening OP2 exposing the second area of the interlayer insulation layer ILD. The second opening OP2 of the via layer VIA may overlap the first contact portion CNT1. The first opening OP1 of the passivation layer PSV and the second opening OP2 of the via layer VIA may be concurrently formed (e.g., simultaneously formed) in the same process. Accordingly, it is possible to reduce the number of masks to simplify a manufacturing process of a display device.

In a process of forming the second opening OP2 of the via layer VIA, the second area of the interlayer insulation layer ILD may be partially etched. Accordingly, the thickness t2 in the third direction (Z-axis direction) of the second area of the interlayer insulation layer (ILD) may be smaller than the thickness t1 in the third direction (Z-axis direction) of the first area of the interlayer insulation layer ILD, but is not limited thereto.

The first insulation layer INS1 may be disposed on the via layer VIA. The first insulation layer INS1 may cover the second area of the interlayer insulation layer ILD. The first insulation layer INS1 may include a third opening OP3 exposing a third area of the interlayer insulation layer ILD. The third opening OP3 of the first insulation layer INS1 may overlap the first contact portion CNT1.

In a process of forming the third opening OP3 of the first insulation layer INS1, the third area of the interlayer insulation layer ILD may be partially etched. Accordingly, a thickness t3 in the third direction (Z-axis direction) of the third area of the interlayer insulation layer ILD may be smaller than the thickness t2 in the third direction (Z-axis direction) of the second area of the interlayer insulation layer ILD, but is not limited thereto.

The first insulation layer INS1 may be configured as a single layer or multilayer, and may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

The second insulation layer INS2 may be disposed on the first insulation layer INS1. The second insulation layer INS2 may cover the third area of the interlayer insulation layer ILD. The above-described first contact portion CNT1 may penetrate the second insulation layer INS2 to expose the first contact electrode CNE1. As an example, the second insulation layer INS2 may include a fourth opening OP4 exposing the first contact electrode CNE1. In a process of forming the fourth opening OP4 of the second insulation layer INS2, the interlayer insulation layer ILD may be etched to form the first contact portion CNT1 exposing the first contact electrode CNE1.

The second insulation layer INS2 may be configured as a single layer or multilayer, and may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

The first connection electrode ELT1 may be disposed on the second insulation layer INS2. The first connection electrode ELT1 may be in contact with the first contact portion CNT1, that is, the first contact electrode CNE1 exposed by the first to fourth openings OP1, OP2, OP3, and OP4. As such, when the first contact electrode CNE1 is configured of the second conductive layer C2 (or the gate conductive layer) and the first connection electrode ELT1 is in direct contact with the first contact electrode CNE1, it is possible to reduce or minimize contact resistance to improve a heat issue and luminance degradation of a display panel. In addition, the first contact electrode CNE1 may be protected by the interlayer insulation layer ILD in a subsequent process. That is, it is possible to prevent the first contact electrode CNE1 from being damaged by an etching solution in the process of etching the third conductive layer C3 and/or the fourth conductive layer C4. This will be described in detail later with reference to FIG. 15 to FIG. 24.

Hereinafter, the light emitting area EMA of the pixel PXL will be described in detail with reference to FIG. 7. The pixel area PXA may include a first light emitting area EMA1, a second light emitting area EMA2, and a third light emitting area EMA3. The first light emitting area EMA1, the second light emitting area EMA2, and the third light emitting area EMA3 may form the light emitting area EMA of the pixel PXL.

The first light emitting part EMU1 disposed in the first light emitting area EMA1 may be electrically connected to the first pixel circuit SPXC1 described above. For example, the first light emitting area EMA1 may be an area in which light is emitted from the light emitting elements LD driven by the first pixel circuit SPXC1. In the described embodiment, the first light emitting area EMA1 may be a light emitting area of the first sub-pixel SPXL1.

The second light emitting part EMU2 disposed in the second light emitting area EMA2 may be electrically connected to the second pixel circuit SPXC2 described above. The second light emitting area EMA2 may be an area in which light is emitted from the light emitting elements LD driven by the second pixel circuit SPXC2. In the described embodiment, the second light emitting area EMA2 may be a light emitting area of the second sub-pixel SPXL2.

The third light emitting part EMU3 disposed in the third light emitting area EMA3 may be electrically connected to the third pixel circuit SPXC3 described above. The third light emitting area EMA3 may be an area in which light is emitted from the light emitting elements LD driven by the third pixel circuit SPXC3. In the described embodiment, the third light emitting area EMA3 may be a light emitting area of the third sub-pixel SPXL3.

For example, the first light emitting area EMA1, the second light emitting area EMA2, and the third light emitting area EMA3 may be partitioned along the first direction (X-axis direction). That is, the second light emitting part EMU2 may be disposed between the first light emitting part EMU1 and the third light emitting part EMU3.

The pixel area PXA may include a non-light emitting area NEA adjacent to the first light emitting area EMA1 (or surrounding a periphery of the first light emitting area EMA1), a non-light emitting area NEA adjacent to the second light emitting area EMA2 (or surrounding a periphery of the second light emitting area EMA2), and a non-light emitting area NEA adjacent to the third light emitting area EMA3 (or surrounding a periphery of the third light emitting area EMA3).

A bank BNK may be disposed in the non-light emitting area NEA. The bank BNK is a structure surrounding the first to third light emitting areas EMA1, EMA2, and EMA3 of each of the first to third sub-pixels SPXL1, SPXL2, and SPXL3, and may be, for example, a pixel defining film. The bank BNK may be disposed in an area between the first to third light emitting areas EMA1, EMA2, and EMA3 and outside the first to third light emitting areas EMA1, EMA2, and EMA3.

The bank BNK may be a dam structure that defines each light emitting area EMA in which the light emitting elements LD should be supplied in a process of supplying the light emitting elements LD to the pixel PXL. For example, the first to third light emitting areas EMA1, EMA2, and EMA3 are partitioned by the bank BNK, so that a mixed solution (for example, ink) including a desired amount and/or type of light emitting elements LD may be injected into each of the first to third light emitting areas EMA1, EMA2, and EMA3.

The bank BNK may include opening areas exposing components disposed below the pixel area PXA. In the described embodiment, the first to third light emitting areas EMA1, EMA2, and EMA3 may be respectively defined by the opening areas of the bank BNK. The first to third light emitting areas EMA1, EMA2, and EMA3 may respectively correspond to the opening areas of the bank BNK.

As the bank BNK is disposed in the non-light emitting area NEA between the first to third light emitting areas EMA1, EMA2, and EMA3, a supply (or injection) area of the light emitting elements LD in the pixel area PXA may be determined. Accordingly, in a step of supplying the light emitting elements LD to the pixel PXL, the light emitting elements LD are prevented from being supplied to unnecessary areas, and the light emitting elements LD may be efficiently supplied to each of the first to third light emitting areas EMA1, EMA2, and EMA3. Accordingly, it is possible to prevent the light emitting elements LD from being unnecessarily wasted, and to reduce the manufacturing cost of the display device.

In the first to third light emitting areas EMA1, EMA2, and EMA3 (or first to third sub-pixel areas SPXA1, SPXA2, and SPXA3), first to third electrodes ALE1, ALE2, and ALE3 may be disposed, respectively.

The first to third electrodes ALE1, ALE2, and ALE3 may extend along the second direction (Y-axis direction), and may be spaced from each other in the first direction (X-axis direction). For example, the first to third electrodes ALE1, ALE2, and ALE3 of the first light emitting area EMA1 (or the first sub-pixel area SPXA1) may be sequentially arranged along the first direction (X-axis direction). In addition, the first to third electrodes ALE1, ALE2, and ALE3 of the second light emitting area EMA2 (or the second sub-pixel area SPXA2) may be sequentially arranged along an opposite direction of the first direction (X-axis direction). In addition, the first to third electrodes ALE1, ALE2, and ALE3 of the third light emitting area EMA3 (or the third sub-pixel area SPXA3) may be sequentially arranged along the first direction (X-axis direction).

Each of the first to third electrodes ALE1, ALE2, and ALE3 may receive a suitable alignment signal (e.g., a predetermined alignment signal) before the light emitting elements LD are aligned in the light emitting area EMA of the pixel PXL, so that it may be used as an electrode (or alignment wire) for aligning the light emitting elements LD.

In the alignment step of the light emitting elements LD, the first electrode ALE1 may receive the first alignment signal, the second electrode ALE2 may receive the second alignment signal, and the third electrode ALE3 may receive the first alignment signal. The above-described first and second alignment signals may be signals having a suitable voltage difference (e.g., a predetermined voltage difference) and/or a suitable phase difference (e.g., a predetermined phase difference) so that light emitting elements LD may be aligned between the first to third electrodes ALE1, ALE2, and ALE3. At least one of the first and second alignment signals may be an AC signal, but is not limited thereto.

The first to third electrodes ALE1, ALE2, and ALE3 may be commonly arranged in the sub-pixels SPXL adjacent thereto. That is, the sub-pixels SPXL may share the first to third electrodes ALE1, ALE2, and ALE3. However, the present disclosure is not necessarily limited thereto, and after the light emitting elements LD are aligned in each of the first to third light emitting areas EMA1, EMA2, and EMA3, a portion of each of the first to third electrodes ALE1, ALE2, and ALE3 positioned between the sub-pixels SPXL adjacent in the second direction (Y-axis direction) may be removed. The first to third electrodes ALE1, ALE2, and ALE3 may be formed of the fourth conductive layer C4.

In one or more embodiments, bank patterns BNP may be disposed under the electrodes ALE. The bank patterns BNP may be provided in at least light emitting area EMA. The bank patterns BNP may extend along a second direction (Y-axis direction), and may be spaced from each other along a first direction (X-axis direction).

As the bank patterns BNP are provided under one area of each of the electrodes ALE, one area of each of the electrodes ALE in areas in which the bank patterns BNP are formed may protrude in an upper direction of the pixel PXL, that is, a third direction (Z-axis direction). When the bank patterns BNP and/or electrodes ALE include a reflective material, a reflective wall structure may be formed around the light emitting elements LD. Accordingly, as light emitted from the light emitting elements LD may be directed in an upper direction (for example, a front direction of the display panel PNL including a suitable viewing angle range (e.g., a predetermined viewing angle range)) of the pixel PXL, light emission efficiency of the pixel PXL may be improved.

Hereinafter, a configuration of the sub-pixel SPXL will be described in detail with reference to FIG. 8. For better understanding and ease of description, configurations and descriptions redundant with those described above will be omitted.

Each sub-pixel SPXL may include the light emitting elements LD, the connection electrodes ELT, and/or the sub-electrodes SLT. As an example, FIG. 8 may be one of the first to third sub-pixels SPXL1, SPXL2, and SPXL3 configuring the pixel PXL of FIG. 3, and the first to third sub-pixels SPXL1, SPXL2, and SPXL3 may be substantially the same or similar to each other. In addition, FIG. 8 illustrates the embodiment in which each sub-pixel SPXL includes the light emitting elements LD disposed in the four serial stages as shown in FIG. 4, but the number of serial stages of each sub-pixel SPXL may be variously changed according to one or more embodiments.

Hereinafter, when arbitrarily referring to one or more light emitting elements from among first to fourth light emitting elements LD1, LD2, LD3, and LD4, or comprehensively referring to two or more light emitting elements, it or they will be referred to as a “light emitting element LD” or “light emitting elements LD”. In addition, when arbitrarily referring to at least one of the electrodes including the first to fifth connection electrodes ELT1, ELT2, ELT3, ELT4, and ELT5, it will be referred to as a “connection electrode ELT” or “connection electrodes ELT”. In addition, when arbitrarily referring to at least one of the electrodes including the first to fourth connection electrodes SLT1, SLT2, SLT3, and SLT4, it will be referred to as a “sub-electrode SLT” or “sub-electrodes SLT”.

Each of the light emitting elements LD may be aligned between the aforementioned electrodes ALE in the light emitting area EMA. In addition, each of the light emitting elements LD may be anastomosis electrically connected between a pair of connection electrodes ELT.

The first light emitting element LD1 may be aligned between the first and second electrodes ALE1 and ALE2 described above. The first light emitting element LD1 may be electrically connected between the first and second electrodes ELT1 and ELT2. As an example, the first light emitting element LD1 may be aligned in a first area (for example, an upper end area) of the first and second electrodes ALE1 and ALE2, and the first end portion EP1 of the first light emitting element LD1 may electrically connected to the first connection electrode ELT1, and the second end portion EP2 of the first light emitting element LD1 may be electrically connected to the second connection electrode ELT2.

The second light emitting element LD2 may be aligned between the first and second electrodes ALE1 and ALE2. The second light emitting element LD2 may be electrically connected between the second and third connection electrodes ELT2 and ELT3. As an example, the second light emitting element LD2 may be aligned in a second area (for example, a lower end area) of the first and second electrodes ALE1 and ALE2, and the first end portion EP1 of the second light emitting element LD2 may electrically connected to the second connection electrode ELT2, and the second end portion EP2 of the second light emitting element LD2 may be electrically connected to the third connection electrode ELT3.

The third light emitting element LD3 may be aligned between the second and third electrodes ALE2 and ALE3 described above. The third light emitting element LD3 may be electrically connected between the third and fourth connection electrodes ELT3 and ELT4. As an example, the third light emitting element LD3 may be aligned in the second area (for example, the lower end area) of the second and third electrodes ALE2 and ALE3, and the first end portion EP1 of the third light emitting element LD3 may electrically connected to the third connection electrode ELT3, and the second end portion EP2 of the third light emitting element LD3 may be electrically connected to the fourth connection electrode ELT4.

The fourth light emitting element LD4 may be aligned between the second and third electrodes ALE2 and ALE3. The fourth light emitting element LD4 may be electrically connected between the fourth and fifth connection electrodes ELT4 and ELT5. As an example, the fourth light emitting element LD4 may be aligned in the first area (for example, the upper end area) of the second and third electrodes ALE2 and ALE3, and the first end portion EP1 of the fourth light emitting element LD4 may electrically connected to the fourth connection electrode ELT4, and the second end portion EP2 of the fourth light emitting element LD4 may be electrically connected to the fifth connection electrode ELT5.

For example, the first light emitting element LD1 may be disposed in an upper left area of the light emitting area EMA, and the second light emitting element LD2 may be disposed in a lower left area of the light emitting area EMA. The third light emitting element LD3 may be disposed in a lower right area of the light emitting area EMA, and the fourth light emitting element LD4 may be disposed in an upper right area of the light emitting area EMA. However, the arrangement and/or connection structure of the light emitting elements LD may be variously changed depending on the structure of the light emitting part EMU and/or the number of serial stages.

Each of the connection electrodes ELT may be at least provided in the light emitting area EMA, and may be disposed to overlap at least one electrode ALE and/or at least one light emitting element LD. For example, each of the connection electrodes ELT may be formed on the electrodes ALE and/or the light emitting elements LD so as to overlap the electrodes ALE and/or the light emitting elements LD to be electrically connected to the light emitting elements LD.

The first connection electrode ELT1 may be disposed on the first area (for example, the upper area) of the second electrode ALE2 and the first end portions EP1 of the first light emitting elements LD1 to be electrically connected to the first end portions EP1 of the first light emitting elements LD1. The first connection electrode ELT1 may be formed of the fifth conductive layer C5.

The second connection electrode ELT2 may be disposed on the first area (for example, the upper end area) of the first electrode ALE1 and the second end portions EP2 of the first light emitting elements LD1 to be electrically connected to the second end portions EP2 of the first light emitting elements LD1. In addition, the second connection electrode ELT2 may be disposed on the second area (for example, the lower end area) of the second electrode ALE2 and the first end portions EP1 of the second light emitting elements LD2 to be electrically connected to the first end portions EP1 of the second light emitting elements LD2. For example, the second connection electrode ELT2 may connect the second end portions EP2 of the first light emitting elements LD1 and the first end portions EP1 of the second light emitting elements LD2 in the light emitting area EMA. For this, the second connection electrode ELT2 may have a curved shape. For example, the second connection electrode ELT2 may have a curved or bent structure at a boundary between an area in which at least one first light emitting element LD1 is arranged and an area in which at least one second light emitting element LD2 is arranged. The second connection electrode ELT2 may be formed of the sixth conductive layer C6.

The third connection electrode ELT3 may be disposed on the second area (for example, the lower end area) of the first electrode ALE1 and the second end portions EP2 of the second light emitting elements LD2 to be electrically connected to the second end portions EP2 of the second light emitting elements LD2. In addition, the third connection electrode ELT3 may be disposed on the second area (for example, the lower end area) of the second electrode ALE2 and the first end portions EP1 of the third light emitting elements LD3 to be electrically connected to the first end portions EP1 of the third light emitting elements LD3. For example, the third connection electrode ELT3 may connect the second end portions EP2 of the second light emitting elements LD2 and the first end portions EP1 of the third light emitting elements LD3 in the light emitting area EMA. For this, the third connection electrode ELT3 may have a curved shape. For example, the third connection electrode ELT3 may have a curved or bent structure at a boundary between an area in which at least one second light emitting element LD2 is arranged and an area in which at least one third light emitting element LD3 is arranged. The third connection electrode ELT3 may be formed of the fifth conductive layer C5.

The fourth connection electrode ELT4 may be disposed on the second area (for example, the lower end area) of the third electrode ALE3 and the second end portions EP2 of the third light emitting elements LD3 to be electrically connected to the second end portions EP2 of the third light emitting elements LD3. In addition, the fourth connection electrode ELT4 may be disposed on the first area (for example, the upper end area) of the second electrode ALE2 and the first end portions EP1 of the fourth light emitting elements LD4 to be electrically connected to the first end portions EP1 of the fourth light emitting elements LD4. For example, the fourth connection electrode ELT4 may connect the second end portions EP2 of the third light emitting elements LD3 and the first end portions EP1 of the fourth light emitting elements LD4 in the light emitting area EMA. For this, the fourth connection electrode ELT4 may have a curved shape. For example, the fourth connection electrode ELT4 may have a curved or bent structure at a boundary between an area in which at least one third light emitting element LD3 is arranged and an area in which at least one fourth light emitting element LD4 is arranged. The fourth connection electrode ELT4 may be formed of the sixth conductive layer C6.

The fifth connection electrode ELT5 may be disposed on the first area (for example, the upper area) of the third electrode ALE3 and the second end portions EP2 of the fourth light emitting elements LD4 to be electrically connected to the second end portions EP2 of the fourth light emitting elements LD4. The fifth connection electrode ELT5 may be formed of the fifth conductive layer C5.

According to the above-described manner, the light emitting elements LD arranged between the electrodes ALE may be connected in a desired shape by using the connection electrodes ELT. For example, the first light emitting elements LD1, the second light emitting elements LD2, the third light emitting elements LD3, and the fourth light emitting elements LD4 may be sequentially connected in series by using the connection electrodes ELT.

The sub-electrodes SLT may be electrically connected to the connection electrodes ELT, respectively. For example, the first sub-electrode SLT1 may be electrically connected to the second connection electrode ELT2, the second sub-electrode SLT2 may be electrically connected to the third connection electrode ELT3, the third sub-electrode SLT3 may be electrically connected to the fourth connection electrode ELT4, and the fourth sub-electrode SLT4 may be electrically connected to the fifth connection electrode ELT5.

The first sub-electrode SLT1 may be formed of the sixth conductive layer C6, the second sub-electrode SLT2 may be formed of the fifth conductive layer C5, the third sub-electrode SLT3 may be formed of the sixth conductive layer C6, and the fourth sub-electrode SLT4 may be formed of the fifth conductive layer C5.

The first sub-electrode SLT1 may be provided integrally with the second connection electrode ELT2, the second sub-electrode SLT2 may be provided integrally with the third connection electrode ELT3, the third sub-electrode SLT3 may be provided integrally with the fourth connection electrode ELT4, and the fourth sub-electrode SLT4 may be provided integrally with the fifth connection electrode ELT5, but the present invention is not limited thereto.

The sub-electrodes SLT may be spaced from the connection electrodes ELT, and the sub-electrodes SLT and the connection electrodes ELT may be electrically connected through connection portions CN1 and CN2, respectively. For example, one ends of the sub-electrodes SLT may be electrically connected to the connection electrodes ELT through the first connection portion CN1. The other ends of the sub-electrodes SLT may be electrically connected to the connection electrodes ELT through the second connection portion CN2. For example, the first connection portion CN1 and/or the second connection portion CN2 may be provided integrally with the sub-electrodes SLT and/or the connection electrodes ELT to be disposed on the same layer, but the present disclosure is not limited thereto.

The sub-electrodes SLT may extend along the second direction (Y-axis direction), and may be spaced from the connection electrodes ELT in the first direction (X-axis direction). The first connection portion CN1 and/or the second connection portion CN2 may extend along the first direction (X-axis direction) between the sub-electrodes SLT and the connection electrodes ELT. As described above, when the sub-electrodes SLT that are electrically connected to the connection electrodes ELT are formed, the dark spot defect of the sub-pixel SPXL may be improved.

Hereinafter, a connection relationship between the sub-electrodes SLT of the sub-pixel SPXL will be described in detail with reference to FIG. 9. For better understanding and ease of description, configurations and descriptions redundant with those described above will be omitted.

At least one of the sub-electrodes SLT of the sub-pixel SPXL may be electrically connected to at least one of the sub-electrodes SLT of the sub-pixel SPXL adjacent thereto. For example, the fourth sub-electrode SLT4 of the first sub-pixel SPXL1 may be electrically connected to the fourth sub-electrode SLT4 of the second sub-pixel SPXL2.

At least one of the sub-electrodes SLT of the sub-pixel SPXL may be electrically connected to at least one of the sub-electrodes SLT of the sub-pixel SPXL adjacent thereto through an intermediate electrode IE. The intermediate electrode IE may be disposed at boundaries of the adjacent sub-pixels SPXL or between the adjacent sub-pixels SPXL to be connected to at least one of the sub-electrodes SLT of each of the adjacent sub-pixels SPXL. For example, the intermediate electrode IE may be provided integrally with at least one of the sub-electrodes SLT of the sub-pixels SPXL to be disposed on the same layer, but is not limited thereto.

The fourth sub-electrode SLT4 of the first sub-pixel SPXL1 may be spaced from the fourth sub-electrode SLT4 of the second sub-pixel SPXL2, and the fourth sub-electrode SLT4 of the first sub-pixel SPXL1 and the fourth sub-electrode SLT4 of the second sub-pixel SPXL2 may be electrically connected through the intermediate electrode IE. The intermediate electrode IE may be provided integrally with the fourth sub-electrode SLT4 of the first sub-pixel SPXL1 and/or the fourth sub-electrode SLT4 of the second sub-pixel SPXL2 to be disposed on the same layer, but is not necessarily limited thereto.

In one or more embodiments, FIG. 9 illustrates the case in which the sub-electrodes SLT of the third sub-pixel SPXL3 are separated from the sub-electrodes SLT of the first sub-pixel SPXL1 and/or the sub-electrodes SLT of the second sub-pixel SPXL2, but the present disclosure is not necessarily limited thereto. In one or more embodiments, at least one of the sub-electrodes SLT of the third sub-pixel SPXL3 may be electrically connected to at least one of the sub-electrodes SLT of the first sub-pixel SPXL1 and/or of the sub-electrodes SLT of the second sub-pixel SPXL2.

At least one of the connection electrodes ELT of each of the sub-pixels SPXL may be electrically connected to each of the pixel circuits SPXC through the contact portion CNT. For example, the first connection electrode ELT1 of the first sub-pixel SPXL1 may be electrically connected to the above-described first contact electrode CNE1 through the first contact portion CNT1. The first connection electrode ELT1 of the second sub-pixel SPXL2 may be electrically connected to the above-described second contact electrode CNE2 through the second contact portion CNT2. The first connection electrode ELT1 of the third sub-pixel SPXL3 may be electrically connected to the above-described third contact electrode CNE3 through the third contact portion CNT3.

Hereinafter, a connection relationship between the sub-electrodes SLT of the sub-pixel SPXL and the power connection line PCL will be described in detail with reference to FIG. 10. For better understanding and ease of description, configurations and descriptions redundant with those described above will be omitted.

At least one of the sub-electrodes SLT of each of the sub-pixels SPXL may be electrically connected to the power connection line PCL. The power connection line PCL may be electrically connected to the above-described second power line PL2 through the contact portion CNT to receive a voltage of the second driving power source VSS.

The fourth sub-electrode SLT4 of each of the sub-pixels SPXL may be electrically connected to the power connection line PCL. The power connection line PCL may extend in the first direction (X-axis direction) between the sub-pixels SPXL in different rows, and the fourth sub-electrodes SLT4 of each of the sub-pixels SPXL may extend along the second directions (Y-axis direction). Accordingly, the power connection line PCL and the fourth sub-electrodes SLT4 of each of the sub-pixels SPXL may have a mesh structure.

The fourth sub-electrode SLT4 of the first sub-pixel SPXL1 may extend in the second direction (Y-axis direction) to be electrically connected to the upper power connection line PCL, the fourth sub-electrode SLT4 of the second sub-pixel SPXL2 may extend in a direction opposite to the second direction (Y-axis direction) to be electrically connected to the lower power connection line PCL, and the fourth sub-electrode SLT4 of the third sub-pixel SPXL3 may extend in the second direction (the Y-axis direction) to be electrically connected to the upper power connection line PCL. However, the connection relationship between the sub-electrodes SLT of each of the sub-pixels SPXL and the power connection line PCL is not necessarily limited thereto. The connection structure of the sub-electrodes SLT and the power connection line PCL may be variously changed in a range in which the sub-electrodes SLT and the power connection line PCL form a mesh structure.

As described above, when the sub-electrodes SLT of the adjacent sub-pixels SPXL are connected to each other and are connected to the power connection line PCL in a mesh structure, by reducing the number of contacts on the power connection line PCL, it is possible to secure a design space in a high-resolution display device, to compensate for the risk of resistance increase, and to improve electrostatic discharge.

Hereinafter, a cross-sectional structure of the sub-pixel SPXL will be described in detail with reference to the light emitting element LD of FIG. 11. FIG. 11 illustrates a light emitting element layer LEL of the sub-pixel SPXL.

Referring to FIG. 11, the sub-pixel SPXL according to the described embodiment includes the bank patterns BNP, the electrodes ALE, the light emitting elements LD, the connection electrodes ELT, and/or the sub-electrodes SLT.

The bank patterns BNP may be disposed on the above-described via layer VIA. The bank patterns BNP may have various shapes according to one or more embodiments. In the described embodiment, the bank patterns BNP may have a shape protruding in the third direction (Z-axis direction) on the substrate SUB. In addition, the bank patterns BNP may be formed to have an inclined surface inclined at a suitable angle (e.g., a predetermined angle) with respect to the substrate SUB. However, the present disclosure is not necessarily limited thereto, and the bank patterns BNP may have a side wall having a curved surface or a step shape. For example, the bank patterns BNP may have a cross-section of a semicircle or semi-ellipse shape.

Electrodes and insulation layers disposed at an upper portion of the bank patterns BNP may have a shape corresponding to the bank patterns BNP. As an example, the electrodes ALE disposed on the bank patterns BNP may include an inclined surface or a curved surface having a shape corresponding to the shape of the bank patterns BNP. Accordingly, the bank patterns BNP, along with the electrodes ALE provided thereon, may function as a reflective member that guides the light emitted from the light emitting elements LD in a front direction of the pixel PXL (Z-axis direction) to improve the light emitting efficiency of the display panel PNL.

The bank patterns BNP may include at least one organic material and/or inorganic material. For example, the bank patterns BNP may include an organic material such as an acrylic resin, an epoxy resin, a phenolic resin, a polyamide resin, a polyimide rein, a polyester resin, a polyphenylenesulfide resin, or a benzocyclobutene (BCB). However, they are not necessarily limited thereto, and the bank patterns BNP may be configured as a single layer or multilayer, and may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

The electrodes ALE may be disposed on the bank patterns BNP. The electrodes ALE may be disposed to be spaced from each other in the sub-pixel SPXL. The electrodes ALE may be formed of the fourth conductive layer C4. The electrodes ALE may be disposed on the same layer as each other. For example, the electrodes ALE may be concurrently formed (e.g., simultaneously formed) in the same process, but is not limited thereto.

The electrodes ALE may receive an alignment signal in the alignment step of the light emitting elements LD. Accordingly, an electric field is formed between the electrodes ALE so that the light emitting elements LD provided to each sub-pixel SPXL may be aligned between the electrodes ALE.

Each of the electrodes ALE may include at least one conductive material. For example, the electrodes ALE may respectively include at least one metal of various metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and copper (Cu), or an alloy including the same; a conductive oxide such as an indium tin oxide (ITO), an indium zinc oxide (IZO), an indium tin zinc Oxide (ITZO), an aluminum zinc oxide (AZO), a gallium zinc oxide (GZO), a zinc tin oxide (ZTO), or a gallium tin oxide (GTO); and at least one conductive material among conductive polymers such as PEDOT, but are not necessarily limited thereto.

The first insulation layer INS1 may be disposed on electrodes ALE. The first insulation layer INS1 has been described with reference to FIG. 6, so duplicate descriptions are omitted.

The bank BNK may be disposed on the first insulation layer INS1. The bank BNK may form a dam structure that partitions the light emitting area in which the light emitting elements LD should be supplied in the step of supplying the light emitting elements LD to each of the sub-pixels SPXL. For example, a desired type and/or amount of light emitting element ink may be supplied to an area partitioned by the bank BNK.

The bank BNK may include an organic material such as an acrylic resin, an epoxy resin, a phenolic resin, a polyamide resin, a polyimide rein, a polyester resin, a polyphenylenesulfide resin, or a benzocyclobutene (BCB). However, it is not necessarily limited thereto, and the bank BNK may be configured as a single layer or multilayer, and may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

In one or more embodiments, the bank BNK may include at least one light blocking and/or reflective material. Accordingly, light leakage between adjacent sub-pixels SPXL may be prevented. For example, the bank BNK may include at least one of a black matrix material and/or a color filter material. For example, the bank BNK may be formed in a black opaque pattern that may block transmission of light. In the described embodiment, a reflective film may be formed on a surface (for example, a side wall) of the bank BNK to increase the light efficiency of each sub-pixel SPXL.

The light emitting elements LD may be disposed on the first insulation layer INS1. The light emitting elements LD may be disposed between the electrodes ALE on the first insulation layer INS1. The light emitting elements LD may be prepared in a form dispersed in light emitting element ink, and may be supplied to each sub-pixel SPXL through an inkjet printing method and the like. For example, the light emitting elements LD may be dispersed in a volatile solvent to be provided in each sub-pixel SPXL. Subsequently, when an alignment signal is supplied to the electrodes ALE, an electric field is formed between the electrodes ALE, so that the light emitting elements LD may be aligned between the electrodes ALE. After the light emitting elements LD are aligned, the light emitting elements LD may be stably arranged between the electrodes ALE by volatilizing the solvent or eliminating it in other ways.

The second insulation layer INS2 may be disposed on the light emitting elements LD. For example, the second insulation layer INS2 is partially provided on the light emitting elements LD, and may expose the first and second end portions EP1 and EP2 of the light emitting elements LD. When the second insulation layer INS2 is formed on the light emitting elements LD after the alignment of the light emitting elements LD is completed, it is possible to prevent the light emitting elements LD from deviating from an aligned position.

The connection electrodes ELT may be disposed on the first and second end portions EP1 and EP2 of the light emitting elements LD exposed by the second insulation layer INS2.

The first connection electrode ELT1 may be directly disposed on the first end portions EP1 of the first light emitting elements LD1 to contact the first end portions EP1 of the first light emitting elements LD1.

In addition, the second connection electrode ELT2 may be directly disposed on the second end portions EP2 of the first light emitting elements LD1 to contact the second end portions EP2 of the first light emitting elements LD1. In addition, the second connection electrode ELT2 may be directly disposed on the first end portions EP1 of the second light emitting elements LD2 to contact the first end portions EP1 of the second light emitting elements LD2. That is, the second connection electrode ELT2 may electrically connect the second end portions EP2 of the first light emitting elements LD1 and the first end portions EP1 of the second light emitting elements LD2.

Similarly, the third connection electrode ELT3 may be directly disposed on the second end portions EP2 of the second light emitting elements LD2 to contact the second end portions EP2 of the second light emitting elements LD2. In addition, the third connection electrode ELT3 may be directly disposed on the first end portions EP1 of the third light emitting elements LD3 to contact the first end portions EP1 of the third light emitting elements LD3. That is, the third connection electrode ELT3 may electrically connect the second end portions EP2 of the second light emitting elements LD2 and the first end portions EP1 of the third light emitting elements LD3.

Similarly, the fourth connection electrode ELT4 may be directly disposed on the second end portions EP2 of the third light emitting elements LD3 to contact the second end portions EP2 of the third light emitting elements LD3. In addition, the fourth connection electrode ELT4 may be directly disposed on the first end portions EP1 of the fourth light emitting elements LD4 to contact the first end portions EP1 of the fourth light emitting elements LD4. That is, the fourth connection electrode ELT4 may electrically connect the second end portions EP2 of the third light emitting elements LD3 and the first end portions EP1 of the fourth light emitting elements LD4.

Similarly, the fifth connection electrode ELT5 may be directly disposed on the second end portions EP2 of the fourth light emitting elements LD4 to contact the second end portions EP2 of the fourth light emitting elements LD4.

The connection electrodes ELT may be formed of a plurality of conductive layers. For example, the first connection electrode ELT1, the third connection electrode ELT3, and/or the fifth connection electrode ELT5 may be formed of the fifth conductive layer C5. For example, the first connection electrode ELT1, the third connection electrode ELT3, and/or the fifth connection electrode ELT5 may be concurrently formed (e.g., simultaneously formed) in the same process. In addition, the second connection electrode ELT2 and/or the fourth connection electrode ELT4 may be formed of the sixth conductive layer C6. For example, the second connection electrode ELT2 and/or the fourth connection electrode ELT4 may be concurrently formed (e.g., simultaneously formed) in the same process. For example, the third insulation layer INS3 may be disposed on the first connection electrode ELT1, the third connection electrode ELT3, and/or the fifth connection electrode ELT5, and the second connection electrode ELT2 and/or the fourth connection electrode ELT4 may be disposed on the third insulation layer INS3. The third insulation layer INS3 may be configured as a single layer or multilayer, and may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

As described above, when the third insulation layer INS3 is disposed between the connection electrodes ELT made of a plurality of conductive layers, because the connection electrodes ELT may be stably separated by the third insulation layer INS3, it is possible to ensure electrical stability between the first and second end portions EP1 and EP2 of the light emitting elements LD.

Each of the connection electrodes ELT may be made of various transparent conductive materials. For example, the connection electrodes ELT may respectively include at least one of various transparent conductive materials including an indium tin oxide (ITO), an indium zinc oxide (IZO), an indium tin zinc oxide (ITZO), an aluminum zinc oxide (AZO), a gallium zinc oxide (GZO), a zinc tin oxide (ZTO), and a gallium tin oxide (GTO), and may be realized to be substantially transparent or translucent to satisfy a desired light transmittance (e.g., a predetermined light transmittance). Accordingly, the light emitted from the first and second end portions EP1 and EP2 of the light emitting elements LD may pass through the connection electrodes ELT to be emitted to the outside of the display panel PNL.

The sub-electrodes SLT may be disposed on the same layer as the connection electrodes ELT, respectively. For example, the sub-electrodes SLT and the connection electrodes ELT that are electrically connected to each other, and the connection portions CN1 and CN2 connecting them, may be integrally provided to be disposed on the same layer.

For example, the first sub-electrode SLT1 may be disposed on the same layer as the second connection electrode ELT2. For example, the first sub-electrode SLT1 may be concurrently formed (e.g., simultaneously formed) in the same process as that of the second connection electrode ELT2, but is not limited thereto. In addition, the second sub-electrode SLT2 may be disposed on the same layer as the third connection electrode ELT3. For example, the second sub-electrode SLT2 may be concurrently formed (e.g., simultaneously formed) in the same process as that of the third connection electrode ELT3, but is not limited thereto. In addition, the third sub-electrode SLT3 may be disposed on the same layer as the fourth connection electrode ELT4. For example, the third sub-electrode SLT3 may be concurrently formed (e.g., simultaneously formed) in the same process as that of the fourth connection electrode ELT4, but is not limited thereto. In addition, the fourth sub-electrode SLT4 may be disposed on the same layer as the fifth connection electrode ELT5. For example, the fourth sub-electrode SLT4 may be concurrently formed (e.g., simultaneously formed) in the same process as that of the fifth connection electrode ELT5, but is not limited thereto.

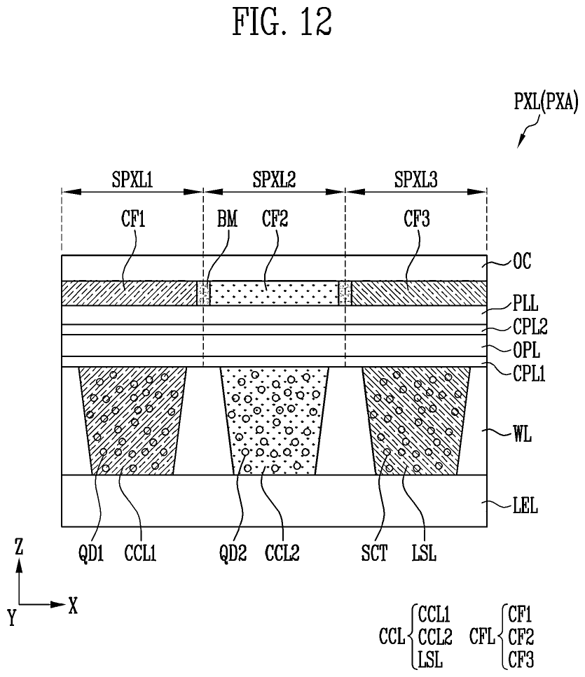

FIG. 12 illustrates a cross-sectional view of the first to third sub-pixels according to the described embodiment.

FIG. 12 illustrates a partition wall WL, a color conversion layer CCL, an optical layer OPL, a color filter layer CFL, and/or an overcoat layer OC provided on the light emitting element layer LEL of the sub-pixel SPXL described above with reference to FIG. 11.

Referring to FIG. 12, the partition wall WL may be disposed on the light emitting element layer LEL of the first to third sub-pixels SPXL1, SPXL2, and SPXL3. For example, the partition wall WL may be disposed between the first to third sub-pixels SPXL1, SPXL2, and SPXL3 or at boundaries therebetween, and may include an opening that respectively overlaps the first to third sub-pixels SPXL1, SPXL2, and SPXL3. The opening of the partition wall WL may provide a space in which the color conversion layer CCL may be provided.

The partition wall WL may include an organic material such as an acrylic resin, an epoxy resin, a phenolic resin, a polyamide resin, a polyimide rein, a polyester resin, a polyphenylenesulfide resin, or a benzocyclobutene (BCB). However, it is not necessarily limited thereto, and the partition wall WL may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

In one or more embodiments, the partition wall WL may include at least one light blocking and/or reflective material. Accordingly, light leakage between adjacent sub-pixels SPXL may be prevented. For example, the partition wall WL may include at least one of a black matrix material and/or a color filter material. For example, the partition wall WL may be formed in a black opaque pattern that may block transmission of light. In the described embodiment, a reflective film may be formed on a surface (for example, a side wall) of the partition wall WL to increase the light efficiency of each sub-pixel SPXL.

The color conversion layer CCL may be disposed on the light emitting element layer LEL in addition to the light emitting elements LD within the opening of the partition wall WL. The color conversion layer CCL may include a first color conversion layer CCL1 disposed on the first sub-pixel SPXL1, a second color conversion layer CCL2 disposed on the second sub-pixel SPXL2, and a scattering layer LSL disposed on the third sub-pixel SPXL3.

In the described embodiment, the first to third sub-pixels SPXL1, SPXL2, and SPXL3 may include the light emitting elements LD that emit light of the same color. For example, the first to third sub-pixels SPXL1, SPXL2, and SPXL3 may include the light emitting elements LD that emit light of a third color (or blue color). The color conversion layer CCL including color conversion particles is disposed on the first to third sub-pixels SPXL1, SPXL2, and SPXL3, respectively, thereby displaying a full-color image.

The first color conversion layer CCL1 may include first color conversion particles that convert light of the third color emitted from the light emitting element LD into light of the first color. For example, the first color conversion layer CCL1 may include a plurality of first quantum dots QD1 dispersed in a suitable matrix material (e.g., a predetermined matrix material) such as a base resin.

In the described embodiment, when the light emitting element LD is a blue light emitting element that emits blue light and the first sub-pixel SPXL1 is a red pixel, the first color conversion layer CCL1 may include a first quantum dot QD1 that converts blue light emitted from the blue light emitting element into red light. The first quantum dot QD1 may absorb blue light to shift a wavelength according to an energy transition to emit red light. In one or more embodiments, when the first sub-pixel SPXL1 is a pixel of a different color, the first color conversion layer CCL1 may include a first quantum dot QD1 corresponding to a color of the first sub-pixel SPXL1.

The second color conversion layer CCL2 may include second color conversion particles that convert light of the third color emitted from the light emitting element LD into light of the second color. For example, the second color conversion layer CCL2 may include a plurality of second quantum dots QD2 dispersed in a suitable matrix material (e.g., a predetermined matrix material) such as a base resin.

In the described embodiment, when the light emitting element LD is a blue light emitting element that emits blue light and the second sub-pixel SPXL2 is a green pixel, the second color conversion layer CCL2 may include a second quantum dot QD2 that converts blue light emitted from the blue light emitting element into green light. The second quantum dot QD2 may absorb blue light to shift a wavelength according to an energy transition to emit green light. In one or more embodiments, when the second sub-pixel SPXL2 is a pixel of a different color, the second color conversion layer CCL2 may include a second quantum dot QD2 corresponding to a color of the second sub-pixel SPXL2.

In the described embodiment, blue light having a relatively short wavelength from among the visible ray bands is incident on the first quantum dot QD1 and the second quantum dot QD2, respectively, thereby increasing an absorption coefficient of the first quantum dot QD1 and the second quantum dot QD2. Accordingly, the efficiency of light emitted from the first sub-pixel SPXL1 and the second sub-pixel SPXL2 may be finally increased, and at the same time, the excellent color reproducibility may be secured. In addition, the light emitting part EMU of the first to third sub-pixels SPXL1, SPXL2, and SPXL3 is configured by using the light emitting elements LD of the same color (for example, the blue color light emitting element), thereby increasing the manufacturing efficiency of the display device.

The scattering layer LSL may be provided to efficiently use the third color (or blue color) light emitted from the light emitting element LD. For example, when the light emitting element LD is a blue light emitting element that emits blue light and the third sub-pixel SPXL3 is a blue pixel, the scattering layer LSL may include at least one type of scatterer SCT to efficiently use the light emitted from the light emitting element LD.

For example, the scattering layer LSL may include a plurality of scatterers SCT dispersed in a suitable matrix material (e.g., a predetermined matrix material) such as a base resin. For example, the scattering layer LSL may include the scatterer SCT such as silica, but materials included in the scatterer SCT are not limited thereto. In one or more embodiments, the scatterer SCT is not disposed only in the third sub-pixel SPXL3, and may be selectively included in the first color conversion layer CCL1 or the second color conversion layer CCL2. In one or more embodiments, the scatterer SCT may be omitted to provide the scattering layer LSL made of a transparent polymer.

A first capping layer CPL1 may be disposed on the color conversion layer CCL. The first capping layer CPL1 may be entirely provided on the first to third sub-pixels SPXL1, SPXL2, and SPXL3. The first capping layer CPL1 may cover the color conversion layer CCL. The first capping layer CPL1 may prevent impurities such as moisture or air from penetrating from the outside to damage or contaminate the color conversion layer CCL.

The first capping layer CPL1 is an inorganic layer, which may include a silicon nitride (SiNx), an aluminum nitride (AINx), a titanium nitride (TiNx), a silicon oxide (SiOx), an aluminum oxide (AlOx), a titanium oxide (TiOx), a silicon oxycarbide (SiOxCy), or a silicon oxynitride (SiOxNy).

The optical layer OPL may be disposed on the first capping layer CPL1. The optical layer OPL may serve to improve light extraction efficiency by recycling light provided from the color conversion layer CCL by total reflection. To this end, the optical layer OPL may have a relatively low refractive index compared to the color conversion layer CCL. For example, the refractive index of the color conversion layer CCL may be about 1.6 to 2.0, and the refractive index of the optical layer OPL may be about 1.1 to 1.3.

A second capping layer CPL2 may be disposed on the optical layer OPL. The second capping layer CPL2 may be entirely provided on the first to third sub-pixels SPXL1, SPXL2, and SPXL3. The second capping layer CPL2 may cover the optical layer OPL. The second capping layer CPL2 may prevent impurities such as moisture or air from penetrating from the outside to damage or contaminate the optical layer OPL.

The second capping layer CPL2 is an inorganic layer, which may include a silicon nitride (SiNx), an aluminum nitride (AINx), a titanium nitride (TiNx), a silicon oxide (SiOx), an aluminum oxide (AlOx), a titanium oxide (TiOx), a silicon oxycarbide (SiOxCy), or a silicon oxynitride (SiOxNy).

A planarization layer PLL may be disposed on the second capping layer CPL2. The planarization layer PLL may be entirely provided on the first to third sub-pixels SPXL1, SPXL2, and SPXL3.

The planarization layer PLL may include an organic material such as an acrylic resin, an epoxy resin, a phenolic resin, a polyamide resin, a polyimide rein, a polyester resin, a polyphenylenesulfide resin, or a benzocyclobutene (BCB). However, it is not necessarily limited thereto, and the planarization layer PLL may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

The color filter layer CFL may be disposed on the planarization layer PLL. The color filter layer CFL may include color filters CF1, CF2, and CF3 matching the color of each pixel PXL. A full-color image may be displayed by disposing the color filters CF1, CF2, and CF3 matching respective colors of the first to third sub-pixels SPXL1, SPXL2, and SPXL3.

The color filter layer CFL may include the first color filter CF1 that is disposed in the first sub-pixel SPXL1 to selectively transmit light emitted by the first sub-pixel SPXL1, the second color filter CF2 that is disposed in the second sub-pixel SPXL2 to selectively transmit light emitted by the second sub-pixel SPXL2, and the third color filter CF3 that is disposed in the third sub-pixel SPXL3 to selectively transmit light emitted by the third sub-pixel SPXL3.

In the described embodiment, the first color filter CF1, the second color filter CF2, and the third color filter CF3 may be a red color filter, a green color filter, and a blue color filter respectively, but the present disclosure is not limited necessarily thereto. Hereinafter, when referring to one of the first color filter CF1, the second color filter CF2, and the third color filter CF3, or when comprehensively referring to two or more thereof, it will be referred to as the “color filter CF” or “color filters CF”.

The first color filter CF1 may overlap the light emitting element layer LEL (or light emitting element LD) of the first sub-pixel SPXL1 and the first color conversion layer CCL1 in the third direction (Z-axis direction). The first color filter CF1 may include a color filter material that selectively transmits light of a first color (or red color). For example, when the first sub-pixel SPXL1 is a red pixel, the first color filter CF1 may include a red color filter material.

The second color filter CF2 may overlap the light emitting element layer LEL (or light emitting element LD) of the second sub-pixel SPXL2 and the second color conversion layer CCL2 in the third direction (Z-axis direction). The second color filter CF2 may include a color filter material that selectively transmits light of a second color (or green color). For example, when the second sub-pixel SPXL2 is a green pixel, the second color filter CF2 may include a green color filter material.

The third color filter CF3 may overlap the light emitting element layer LEL (or light emitting element LD) and the scattering layer LSL of the third sub-pixel SPXL3 in the third direction (Z-axis direction). The third color filter CF3 may include a color filter material that selectively transmits light of a third color (or blue color). For example, when the third sub-pixel SPXL3 is a blue pixel, the third color filter CF3 may include a blue color filter material.

A light blocking layer BM may be disposed between the first to third color filters CF1, CF2, and CF3, and the light blocking layer BM may be disposed between the first to third sub-pixels SPXL1, SPXL2, and SPXL3 or at the boundaries therebetween. The material of the light blocking layer BM is not particularly limited, and may be made of various light blocking materials including a black matrix. As such, when the light blocking layer BM is formed between the first to third color filters CF1, CF2, and CF3, color mixing defects viewed from the front or side of the display device may be prevented or reduced.

The overcoat layer OC may be disposed on the color filter layer CFL. The overcoat layer OC may be entirely provided on the first to third sub-pixels SPXL1, SPXL2, and SPXL3. The overcoat layer OC may cover the color filter layer CFL and a lower member thereof. The overcoat layer OC may prevent moisture or air from penetrating into the above-mentioned lower members that are disposed therebelow. In addition, the overcoat layer OC may protect the above-mentioned lower members from foreign matters such as dust.

The overcoat layer OC may include an organic material such as an acrylic resin, an epoxy resin, a phenolic resin, a polyamide resin, a polyimide rein, a polyester resin, a polyphenylenesulfide resin, or a benzocyclobutene (BCB). However, it is not necessarily limited thereto, and the overcoat layer OC may include a silicon oxide (SiOx), a silicon nitride (SiNx), a silicon oxynitride (SiOxNy), an aluminum nitride (AINx), an aluminum oxide (AlOx), a zirconium oxide (ZrOx), a hafnium oxide (HfOx), or a titanium oxide (TiOx), and various types of inorganic materials.

According to the above-described embodiment, it is possible to prevent damage to the contact electrodes CNE of the contact portion CNT, and concurrently (e.g., simultaneously), to reduce or minimize the contact resistance of the contact portion CNT to improve the heat issue and luminance degradation of the display panel PNL.

Hereinafter, another embodiment will be described. The same elements as those described above will be referred to the same reference numerals in embodiments below, and redundant descriptions will be omitted or simplified.

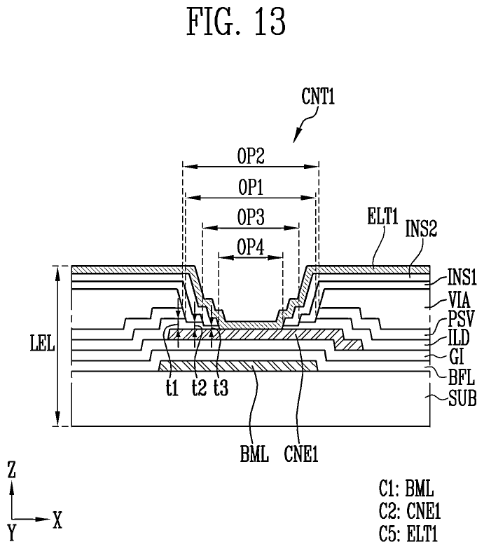

FIG. 13 illustrates a cross-sectional view of a contact portion according to one or more embodiments.

Referring to FIG. 13, the present embodiment may further include a lower metal layer BML overlapping the first contact portion CNT1. That is, the lower metal layer BML may be disposed to overlap the first contact electrode CNE1 in the third direction (e.g., Z-axis direction). As such, when the lower metal layer BML is formed, a step (e.g., a predetermined step) is formed under the contact electrodes CNE, so that the interlayer insulation layer ILD on the contact electrodes CNE may be easily etched. Accordingly, it is possible to prevent the interlayer insulation layer ILD from remaining on the contact electrodes CNE in the process of forming the contact portion CNT.

The lower metal layer BML may be formed of the first conductive layer C1. For example, the lower metal layer BML may be disposed between the substrate SUB and the buffer layer BFL. The lower metal layer BML may be electrically connected to at least one of the first to third lower metal layers BML1, BML2, and BML3 described with reference to FIG. 5, but is not necessarily limited thereto.

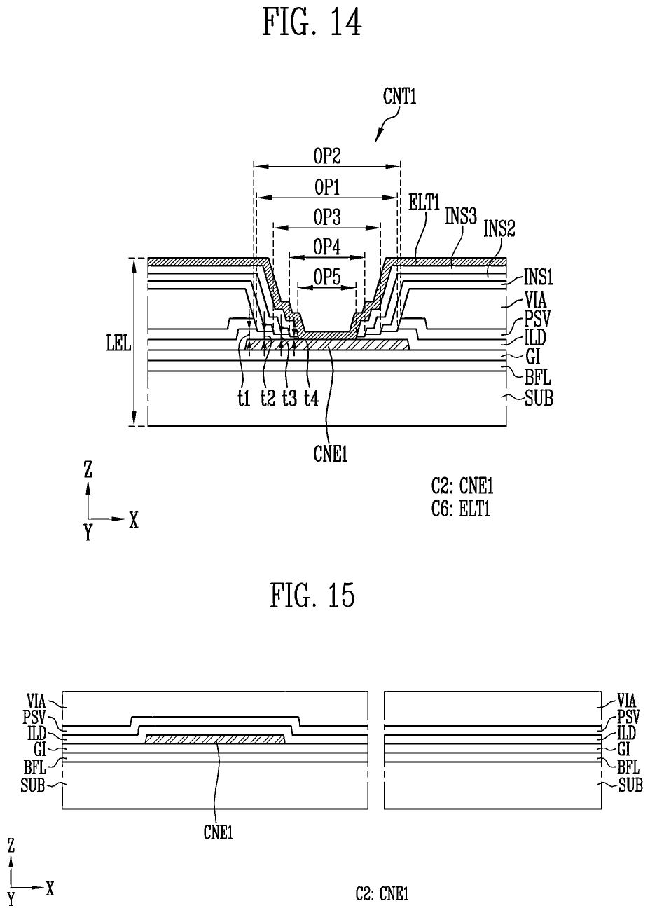

FIG. 14 illustrates a cross-sectional view of a contact portion according to one or more embodiments.

Referring to FIG. 14, the second insulation layer INS2 may cover the third area of the interlayer insulation layer ILD. The second insulation layer INS2 may include the fourth opening OP4 exposing a fourth area of the interlayer insulation layer ILD. The fourth opening OP4 of the second insulation layer INS2 may overlap the first contact portion CNT1.

In a process of forming the fourth opening OP4 of the second insulation layer INS2, the fourth area of the interlayer insulation layer ILD may be partially etched. Accordingly, a thickness t4 in the third direction (Z-axis direction) of the fourth area of the interlayer insulation layer ILD may be smaller than the thickness t3 in the third direction (Z-axis direction) of the third area of the interlayer insulation layer ILD, but is not limited thereto.

The third insulation layer INS3 may be further disposed on the second insulation layer INS2. The third insulation layer INS3 may cover the fourth area of the interlayer insulation layer ILD. The first contact portion CNT1 may penetrate the third insulation layer INS3 to expose the first contact electrode CNE1. For example, the third insulation layer INS3 may include a fifth opening OP5 exposing the first contact electrode CNE1. In a process of forming the fifth opening OP5 of the third insulation layer INS3, the interlayer insulation layer ILD may be etched to form the first contact portion CNT1 exposing the first contact electrode CNE1.

The first connection electrode ELT1 may be disposed on the third insulation layer INS3. In this case, the first connection electrode ELT1 may be formed of the sixth conductive layer C6. The first connection electrode ELT1 may be in contact with the first contact portion CNT1, that is, the first contact electrode CNE1 exposed by the first to fifth openings OP1, OP2, OP3, OP4, and OP5.

Subsequently, a manufacturing method of the display device according to the above-described embodiment will be described.

FIG. 15 to FIG. 24 illustrate cross-sectional views of process steps of a manufacturing method of a display device according to one or more embodiments. FIG. 15 to FIG. 24 are cross-sectional views for explaining the manufacturing method of the display device of FIG. 6 and FIG. 11, and constituent elements that are substantially the same as those of FIG. 6 and FIG. 11 are denoted by the same reference numerals, and detailed descriptions thereof will be omitted.

Referring to FIG. 15, first, the first contact electrode CNE1 is formed. The buffer layer BFL and the gate insulation layer GI may be formed on the substrate SUB, and the first contact electrode CNE1 may be formed on the gate insulation layer GI. The interlayer insulation layer ILD, the passivation layer PSV, and/or the via layer VIA may be sequentially formed on the first contact electrode CNE1. As described with reference to FIG. 6, in order to reduce or minimize the contact resistance of the contact portion CNT, the second conductive layer C2 including the first contact electrode CNE1 may be formed as a multilayer in which titanium (Ti), copper (Cu), and/or an indium tin oxide (ITO) are sequentially or repeatedly stacked. Accordingly, because the contact resistance due to an oxide film (for example, an aluminum oxide film) may be improved, the heat issue of the contact portion CNT and luminance degradation of the display panel PNL may be improved as described above.

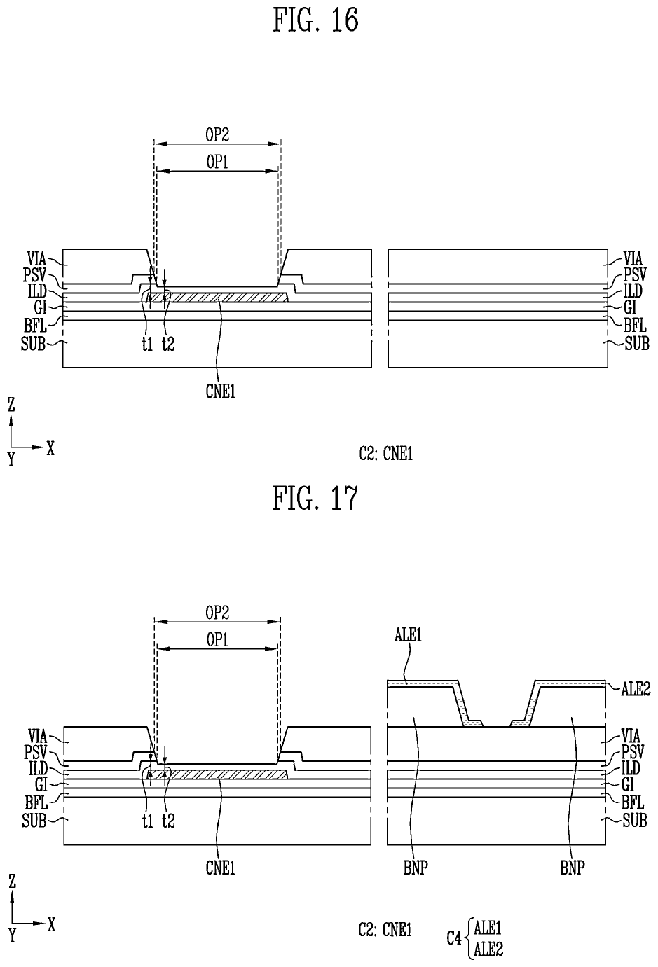

Referring to FIG. 16, then the passivation layer PSV and the via layer VIA are etched. The passivation layer PSV and the via layer VIA may cover the first area of the interlayer insulation layer ILD, but may be etched to expose the second area of the interlayer insulation layer ILD. For example, the first opening OP1 exposing the second area of the interlayer insulation layer ILD may be formed by etching the passivation layer PSV. In addition, the second opening OP2 exposing the second area of the interlayer insulation layer ILD may be formed by etching the via layer VIA. The passivation layer PSV and the via layer VIA may be concurrently etched (e.g., simultaneously etched) in the same process. That is, the first opening OP1 of the passivation layer PSV and the second opening OP2 of the via layer VIA may be concurrently formed (e.g., simultaneously formed). Accordingly, the manufacturing process may be simplified by reducing the number of masks. As described above, when the passivation layer PSV and the via layer VIA are concurrently etched (e.g., simultaneously etched), the etching surfaces of the passivation layer PSV and the via layer VIA may form the same planar surface.

In the process of etching the passivation layer PSV and the via layer VIA, the interlayer insulation layer ILD disposed thereunder may be primarily etched. For example, the first opening OP1 of the passivation layer PSV and the second opening OP2 of the via layer VIA are formed, and over-etching is performed, so that the interlayer insulation layer ILD exposed by the first opening OP1 of the passivation layer PSV and the second opening OP2 of the via layer VIA may be partially removed. In this case, the thickness t2 in the third direction (Z-axis direction) of the second area of the interlayer insulation layer ILD exposed by the first opening OP1 of the passivation layer PSV and the second opening OP2 of the via layer VIA may be smaller than the thickness t1 in the third direction (Z-axis direction) of the first area of the interlayer insulation layer ILD covered by the passivation layer PSV and the via layer VIA. As such, when the interlayer insulation layer ILD is primarily etched to be partially removed, it is possible to protect the first contact electrode CNE1 with the interlayer insulation layer ILD and to prevent the interlayer insulation layer ILD from remaining in the first contact portion CNT1 in a subsequent process. In addition, when the interlayer insulation layer ILD is primarily etched by over-etching the passivation layer PSV and the via layer VIA, because an additional mask for primarily etching the interlayer insulation layer ILD is unnecessary, process economics may be secured.

Referring to FIG. 17, the bank patterns BNP and the electrodes ALE are then formed on the via layer VIA. The electrodes ALE may be formed of the fourth conductive layer C4. As described above, when the first contact electrode CNE1 is formed of the second conductive layer C2 (or the gate conductive layer), because the first contact electrode CNE1 may be protected by the interlayer insulation layer ILD, it may be prevented from being damaged by the etchant in the process of forming the fourth conductive layer C4 as described above.

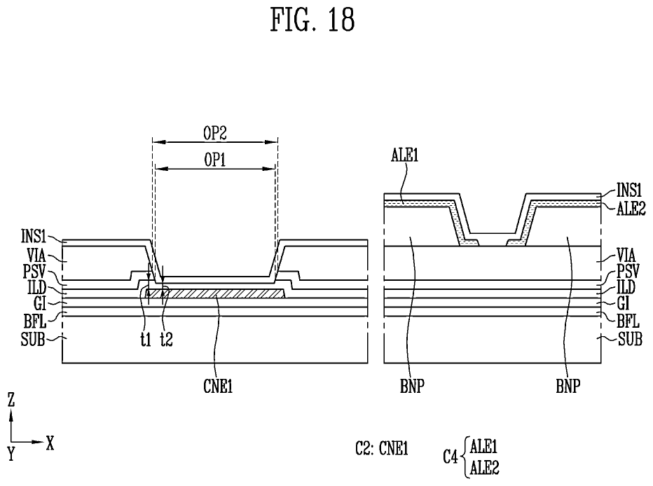

Referring to FIG. 18, the first insulation layer INS1 is then formed. The first insulation layer INS1 may cover the second area of the interlayer insulation layer ILD exposed by the first opening OP1 of the passivation layer PSV and the second opening OP2 of the via layer VIA. In addition, the first insulation layer INS1 may cover the electrodes ALE.

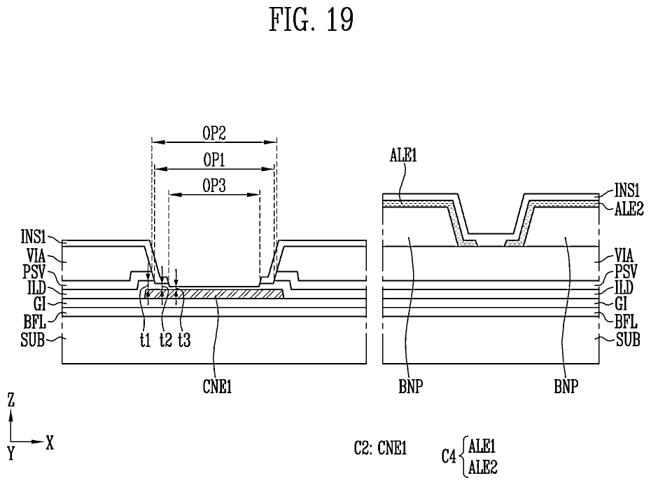

Referring to FIG. 19, the first insulation layer INS1 is etched. The first insulation layer INS1 may cover the second area of the interlayer insulation layer (ILD), but may be etched to expose the third area of the interlayer insulation layer ILD. For example, the third opening OP3 exposing the third area of the interlayer insulation layer ILD may be formed by etching the first insulation layer INS1.

In the process of etching the first insulation layer INS1, the interlayer insulation layer ILD disposed therebelow may be secondarily etched. For example, the interlayer insulation layer ILD exposed by the third opening OP3 of the first insulation layer INS1 may be partially removed by forming the third opening OP3 of the first insulation layer INS1 and performing over-etching for it. In this case, the thickness t3 in the third direction (Z-axis direction) of the third area of the interlayer insulation layer ILD exposed by the third opening OP3 of the first insulation layer INS1 may be smaller than the thickness t2 in the third direction (Z-axis direction) of the second area of the interlayer insulation layer ILD covered by the first insulation layer INS1. As such, when the interlayer insulation layer ILD is secondarily etched to be partially removed, it is possible to protect the first contact electrode CNE1 with the interlayer insulation layer ILD and to prevent the interlayer insulation layer ILD from remaining in the first contact portion CNT1 in a subsequent process. In addition, when the interlayer insulation layer ILD is secondarily etched by over-etching the first insulation layer INS1, because an additional mask for secondary etching the interlayer insulation layer ILD is unnecessary, process economics may be secured.

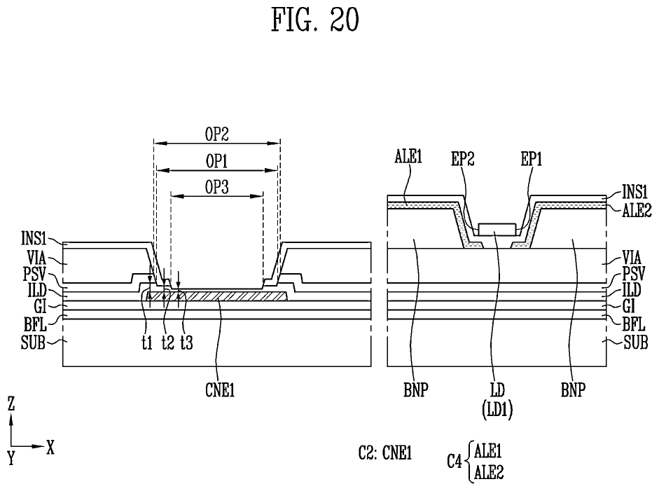

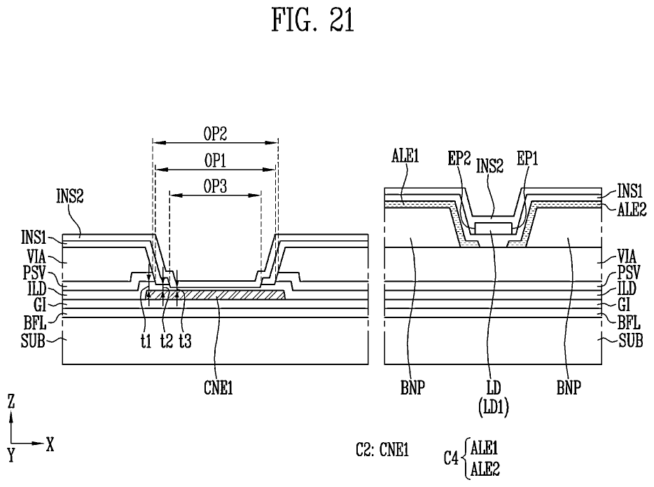

Referring to FIG. 20, the light emitting elements LD are then provided between the electrodes ALE. The light emitting elements LD may be prepared in a form dispersed in light emitting element ink, and may be supplied through an inkjet printing method and the like. For example, the light emitting elements LD may be dispersed in a volatile solvent to be provided. Subsequently, when an alignment signal is supplied to the electrodes ALE, an electric field is formed between the electrodes ALE, so that the light emitting elements LD may be aligned between the electrodes ALE. After the light emitting elements LD are aligned, the light emitting elements LD may be stably arranged between the electrodes ALE by volatilizing the solvent or eliminating it in other ways.

Referring to FIG. 21, the second insulation layer INS2 is then formed. The second insulation layer INS2 may cover the third area of the interlayer insulation layer ILD exposed by the third opening OP3 of the first insulation layer INS1. In addition, the second insulation layer INS2 may cover the light emitting elements LD.

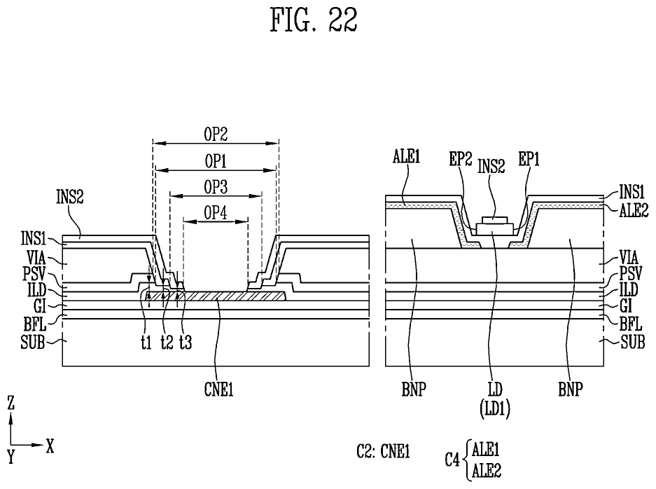

Referring to FIG. 22, the second insulation layer INS2 is then etched. The second insulation layer INS2 may cover the third area of the interlayer insulation layer ILD, but may be etched to expose the first contact electrode CNE1. For example, the fourth opening OP4 exposing the first contact electrode CNE1 may be formed by etching the second insulation layer INS2.

In the process of etching the second insulation layer INS2, by etching the interlayer insulation layer ILD disposed thereunder, the first contact portion CNT1 may be formed. In this case, the etching surface of the first contact portion CNT1, that is, the second insulation layer INS2 and the interlayer insulation layer ILD may form the same planar surface. For example, by forming the fourth opening OP4 of the second insulation layer INS2 and performing over-etching for it, the interlayer insulation layer ILD may be completely removed. Accordingly, the first contact electrode CNE1 may be exposed through the first to fourth openings OP1, OP2, OP3, and OP4 described above.

As described above, when the interlayer insulation layer ILD is sequentially removed by the primarily to thirdly etching, it is possible to protect the first contact electrode CNE1 and to prevent the interlayer insulation layer ILD from remaining on the first contact portion CNT1. In addition, when the interlayer insulation layer ILD is thirdly etched by over-etching the second insulation layer INS2, because an additional mask for thirdly etching the interlayer insulation layer ILD is unnecessary, process economics may be secured.

In addition, the end portions EP1 and EP2 of the light emitting elements LD may be exposed by etching the second insulation layer INS2.

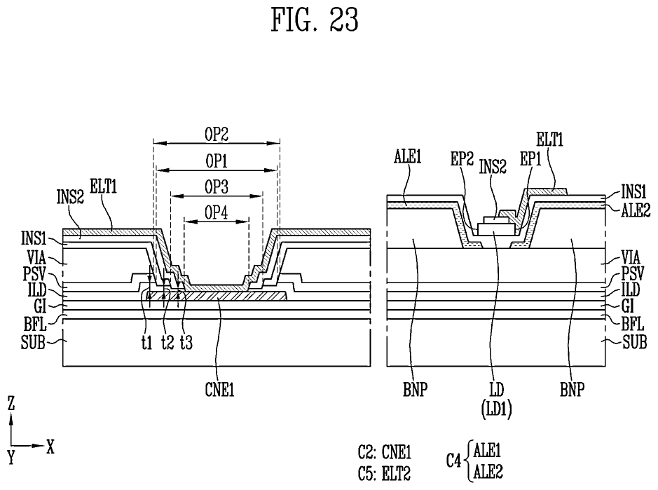

Referring to FIG. 23, the first connection electrode ELT1 is then formed. The first connection electrode ELT1 may be in contact with the first contact portion CNT1, that is, the first contact electrode CNE1 exposed by the first to fourth openings OP1, OP2, OP3, and OP4.

In addition, the first connection electrode ELT1 may be formed on the light emitting elements LD. The first connection electrode ELT1 may contact the first end portions EP1 of the light emitting elements LD exposed by the second insulation layer INS2. The first connection electrode ELT1 may be formed of the fifth conductive layer C5.

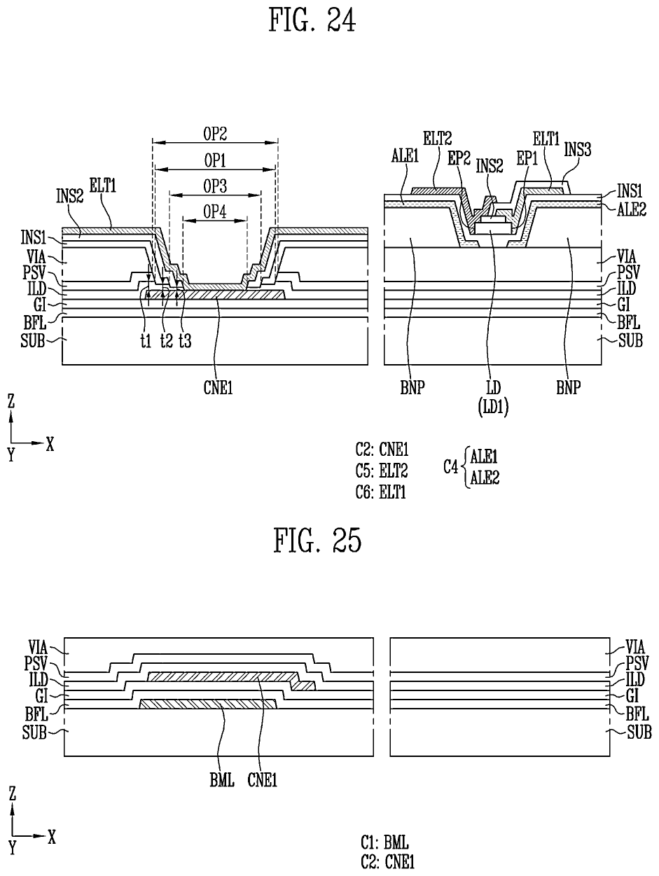

Referring to FIG. 24, the third insulation layer INS3 is then formed, and the second connection electrode ELT2 is formed on the third insulation layer INS3 to be able to complete the display device of FIG. 6 and FIG. 11. The third insulation layer INS3 may cover the first connection electrode ELT1, but may be partially removed to expose the second end portions EP2 of the light emitting elements LD. The second connection electrode ELT2 may be in contact with the second end portions EP2 of the light emitting elements LD exposed by the third insulation layer INS3. The second connection electrode ELT2 may be formed of the sixth conductive layer C6.

According to the above-described embodiment, as the interlayer insulation layer ILD is sequentially removed by the first to third etching process, it is possible to prevent the interlayer insulation layer ILD from remaining in the contact portion CNT. In addition, as the interlayer insulation layer ILD is partially etched by over-etching the insulation layers disposed at the upper portion of the interlayer insulation layer ILD, an additional mask for etching the interlayer insulation layer ILD is unnecessary, process economics may be secured.

Hereinafter, another embodiment will be described. The same elements as those described above will be referred to the same reference numerals in embodiments below, and redundant descriptions will be omitted or simplified.

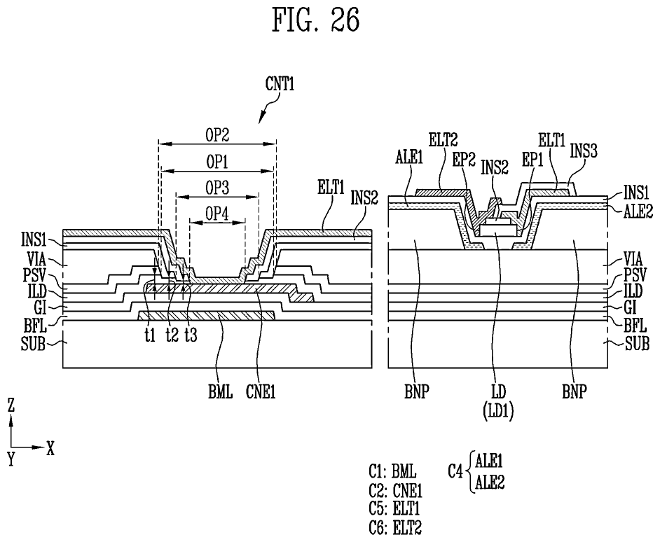

FIG. 25 and FIG. 26 illustrate cross-sectional views of process steps of a manufacturing method of a display device according to one or more embodiments. FIG. 25 and FIG. 26 are cross-sectional views for explaining the manufacturing method of the contact portion of FIG. 13, and constituent elements that are substantially the same as those of FIG. 13 are denoted by the same reference numerals, and detailed descriptions thereof will be omitted.

Referring to FIG. 25, first, the lower metal layer BML and the first contact electrode CNE1 are formed. The lower metal layer BML may be formed on the substrate SUB, and the buffer layer BFL and the gate insulation layer GI may be formed on the lower metal layer BML. The first contact electrode CNE1 may be formed on the gate insulation layer GI, and the interlayer insulation layer ILD, the passivation layer PSV, and/or the via layer VIA may be sequentially formed on the first contact electrode CNE1.

Referring to FIG. 26, the interlayer insulation layer ILD on the first contact electrode CNE1 is sequentially removed by the first to third etching process, and the first connection electrode ELT1 is formed on the first contact electrode CNE1. Because the above process has been described with reference to FIG. 16 to FIG. 24, duplicate contents will be omitted.

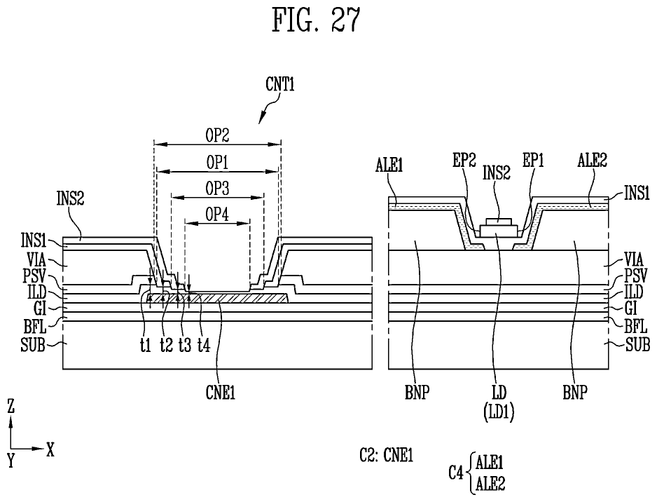

FIG. 27 to FIG. 31 illustrate cross-sectional views of process steps of a manufacturing method of a display device according to one or more embodiments. FIG. 27 to FIG. 31 are cross-sectional views for explaining the manufacturing method of the contact portion of FIG. 14, and constituent elements that are substantially the same as those of FIG. 14 are denoted by the same reference numerals, and detailed descriptions thereof will be omitted.

Referring to FIG. 27, the second insulation layer INS2 is etched. Because the steps of forming the layers up to the second insulation layer INS2 have been described with reference to FIG. 15 to FIG. 21, duplicate descriptions will be omitted.

The second insulation layer INS2 may cover the third area of the interlayer insulation layer ILD, but may be etched to expose the fourth area of the interlayer insulation layer ILD. For example, the second insulation layer INS2 may be etched to form the fourth opening OP4 exposing the fourth area of the interlayer insulation layer ILD.

In the process of etching the second insulation layer INS2, the interlayer insulation layer ILD disposed thereunder may be thirdly etched. For example, the interlayer insulation layer ILD exposed by the fourth opening OP4 of the second insulation layer INS2 may be partially removed by forming the fourth opening OP4 of the second insulation layer INS2 and performing over-etching for it. In this case, the thickness t4 in the third direction (Z-axis direction) of the fourth area of the interlayer insulation layer ILD exposed by the fourth opening OP4 of the second insulation layer INS2 may be smaller than the thickness t3 in the third direction (Z-axis direction) of the third area of the interlayer insulation layer ILD covered by the second insulation layer INS2. As such, when the interlayer insulation layer ILD is thirdly etched to be partially removed, it is possible to protect the first contact electrode CNE1 with the interlayer insulation layer ILD and to prevent the interlayer insulation layer ILD from remaining in the first contact portion CNT1 in a subsequent process. In addition, when the interlayer insulation layer ILD is thirdly etched by over-etching the second insulation layer INS2, because an additional mask for thirdly etching the interlayer insulation layer ILD is unnecessary, process economics may be secured.

In addition, the end portions EP1 and EP2 of the light emitting elements LD may be exposed by etching the second insulation layer INS2.

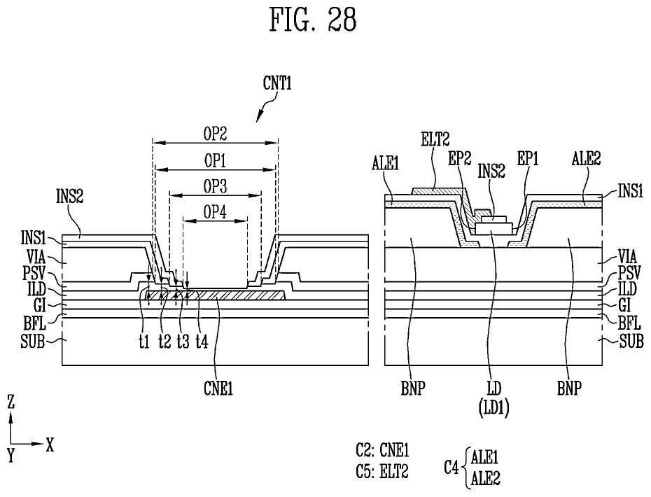

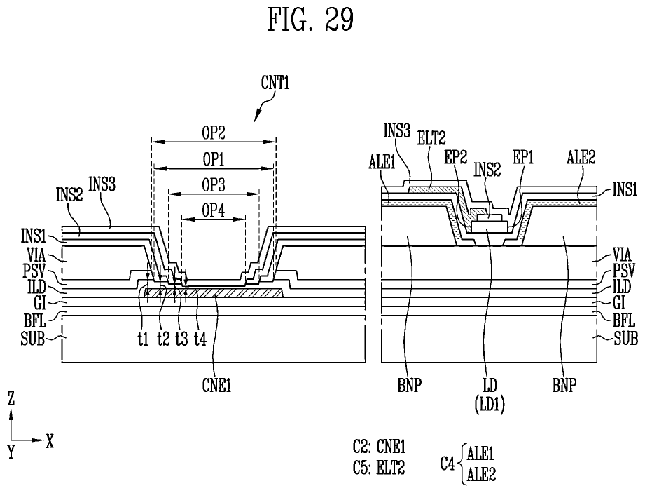

Referring to FIG. 28, the second connection electrode ELT2 is then formed. The second connection electrode ELT2 may be formed on the light emitting elements LD. The second connection electrode ELT2 may be in contact with the second end portions EP2 of the light emitting elements LD exposed by the second insulation layer INS2. The second connection electrode ELT2 may be formed of the fifth conductive layer C5.

Referring to FIG. 29, the third insulation layer INS3 is then formed. The third insulation layer INS3 may cover the fourth area of the interlayer insulation layer ILD exposed by the fourth opening OP4 of the second insulation layer INS2. In addition, the third insulation layer INS3 may cover the second connection electrode ELT2 and the light emitting elements LD.

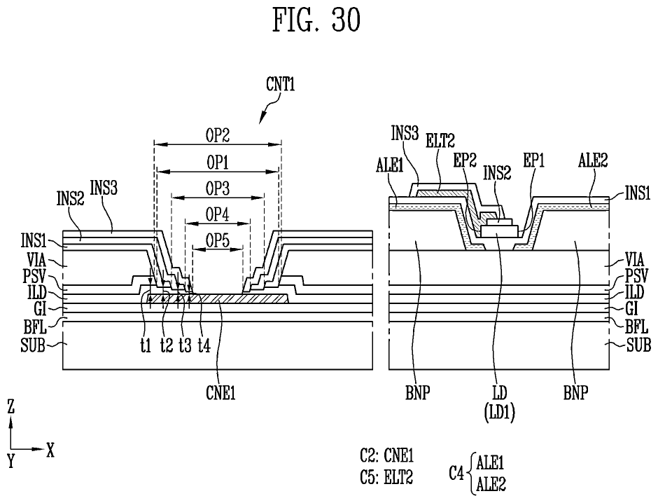

Referring to FIG. 30, the third insulation layer INS3 is then etched. The third insulation layer INS3 may cover the fourth area of the interlayer insulation layer ILD, but may be etched to expose the first contact electrode CNE1. For example, the fifth opening OP5 exposing the first contact electrode CNE1 may be formed by etching the third insulation layer INS3.

In the process of etching the third insulation layer INS3, by fourth-etching the interlayer insulation layer ILD disposed thereunder, the first contact portion CNT1 may be formed. In this case, the etching surface of the first contact portion CNT1, that is, the third insulation layer INS3 and the interlayer insulation layer ILD may form the same planar surface. For example, by forming the fourth opening OP4 of the third insulation layer INS3 and performing over-etching for it, the interlayer insulation layer ILD may be completely removed. Accordingly, the first contact electrode CNE1 may be exposed through the first to fifth openings OP1, OP2, OP3, OP4, and OP5 described above.

As described above, when the interlayer insulation layer ILD is sequentially removed by first to fourth etching, it is possible to protect the first contact electrode CNE1 and to prevent the interlayer insulation layer ILD from remaining on the first contact portion CNT1. In addition, when the interlayer insulation layer ILD is fourth-etched by over-etching the third insulation layer INS3, because an additional mask for fourth-etching the interlayer insulation layer ILD is unnecessary, process economics may be secured.

In addition, the first end portions EP1 of the light emitting elements LD may be exposed by etching the third insulation layer INS3.

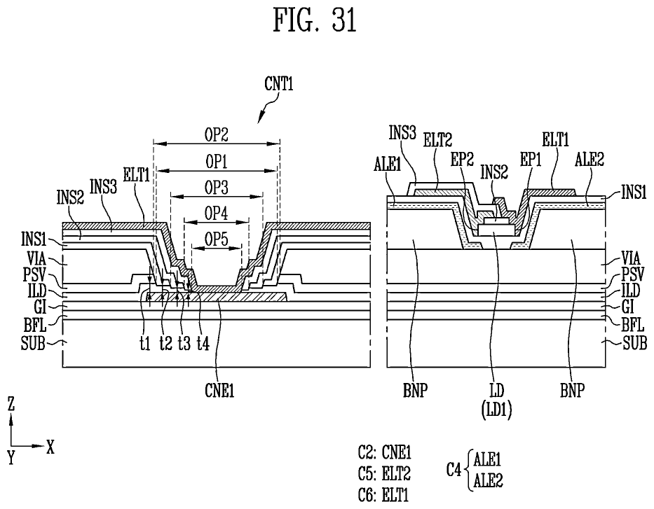

Referring to FIG. 31, the first connection electrode ELT1 is then formed on the third insulation layer INS3. The first connection electrode ELT1 may be in contact with the first contact portion CNT1, that is, the first contact electrode CNE1 exposed by the first to fifth openings OP1, OP2, OP3, OP4, and OP5.

In addition, the first connection electrode ELT1 may be formed on the light emitting elements LD. The first connection electrode ELT1 may contact the first end portions EP1 of the light emitting elements LD exposed by the third insulation layer INS3. The first connection electrode ELT1 may be formed of the sixth conductive layer C6.

Those skilled in the art related to the present embodiment will readily appreciate that many modifications are possible without materially departing from the novel teachings and advantages. The embodiments should be considered in a descriptive sense only and not for purposes of limitation. The scope of the present invention, not by the detailed description given in the appended claims, and all differences within the equivalent scope will be construed as being included in the present disclosure.

What is claimed is:

1. A display device comprising:
contact electrodes on a substrate;
an interlayer insulation layer on the contact electrodes;
a passivation layer on the interlayer insulation layer;
pixel electrodes on the passivation layer;
a first insulation layer on the pixel electrodes;
light emitting elements between the pixel electrodes; and
connection electrodes electrically connected to the light emitting elements,
wherein the passivation layer and/or the first insulation layer include an opening exposing the interlayer insulation layer, and
the connection electrodes are in contact with the contact electrodes through a contact portion penetrating the interlayer insulation layer exposed by the opening.

2. The display device of claim 1, further comprising
a second insulation layer between the light emitting elements and the connection electrodes.

3. The display device of claim 2, wherein
the contact portion penetrates the second insulation layer to expose the contact electrodes.

4. The display device of claim 2, wherein
the connection electrodes comprise a first connection electrode in contact with first end portions of the light emitting elements, and a second connection electrode in contact with second end portions of the light emitting elements.

5. The display device of claim 4, wherein
the first connection electrode is in contact with the contact electrodes.

6. The display device of claim 4, further comprising
a third insulation layer between the first connection electrode and the second connection electrode.

7. The display device of claim 6, wherein
the second insulation layer includes an opening exposing the interlayer insulation layer.

8. The display device of claim 6, wherein
the contact portion penetrates the third insulation layer to expose the contact electrodes.

9. The display device of claim 1, wherein
the passivation layer covers a first area of the interlayer insulation layer, and includes a first opening exposing a second area of the interlayer insulation layer.

10. The display device of claim 9, wherein
a thickness of the first area of the interlayer insulation layer is greater than a thickness of the second area thereof.

11. The display device of claim 9, further comprising
a via layer between the passivation layer and the pixel electrodes.

12. The display device of claim 11, wherein
the via layer covers the first area of the interlayer insulation layer, and includes a second opening exposing the second area of the interlayer insulation layer.

13. The display device of claim 9, wherein
the first insulation layer covers the second area of the interlayer insulation layer, and includes a third opening exposing a third area of the interlayer insulation layer.

14. The display device of claim 13, wherein
the thickness of the second area of the interlayer insulation layer is greater than a thickness of the third area thereof.

15. The display device of claim 1, further comprising
a lower metal layer between the substrate and the contact electrodes,
wherein the lower metal layer overlaps the contact portion.

16. A manufacturing method of a display device, comprising:
forming contact electrodes on a substrate;
forming an interlayer insulation layer on the contact electrodes;
forming a passivation layer on the interlayer insulation layer;
forming a first opening by etching the passivation layer;
first-etching the interlayer insulation layer through the first opening of the passivation layer;
forming pixel electrodes on the passivation layer;
providing light emitting elements between the pixel electrodes; and
forming connection electrodes on the light emitting elements;
wherein the connection electrodes are in contact with the contact electrodes through a contact portion penetrating the interlayer insulation layer.

17. The manufacturing method of the display device of claim 16, further comprising:
forming a via layer on the passivation layer; and
forming a second opening by etching the via layer.

18. The manufacturing method of the display device of claim 17, wherein
the first opening of the passivation layer and the second opening of the via layer are concurrently formed.

19. The manufacturing method of the display device of claim 17, further comprising:
forming a first insulation layer on the pixel electrodes;
forming a third opening by etching the first insulation layer; and
second-etching the interlayer insulation layer through the third opening of the first insulation layer.

20. The manufacturing method of the display device of claim 19, further comprising:
forming a second insulation layer on the light emitting elements;
forming a fourth opening by etching the second insulation layer; and
forming the contact portion by third-etching the interlayer insulation layer through the fourth opening of the second insulation layer.
